(19) United States
(12) Patent Application Publication
(10) Pub. No.: US 2006/0199373 A1
(43) Pub. Date: Sep. 7, 2006

(54) Method of manufacturing semiconductor device

(76) Inventors: Hideshi Miyajima, Yokohama-shi (JP); Hideaki Masuda, Yokohama-shi (JP); Tsutomu Shimayama, Yokohama-shi (JP); Shunichi Shibuki, Isehara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/360,703

(22) Filed: Feb. 24, 2006

(30) Foreign Application Priority Data
Feb. 25, 2005 (JP) 2005-050939

(51) Int. Cl. H01L 21/4763

(52) U.S. Cl. 438/629; 257/E21.585

(57) ABSTRACT

A manufacturing method of a semiconductor device, comprising providing a low-relative-dielectric-constant film above a substrate containing at least oxygen and having a relative dielectric constant of 3.3 or more, a conductor being to be buried in the film, performing a plasma processing by discharging a gas containing a noble gas as a main component to the film, the plasma processing being executed while the substrate above which the film is provided is storing in a processing chamber having an inside covered with a material composed of an element except for oxygen and substantially set under an oxygen-free atmosphere, and providing a first insulating film above the low-relative-dielectric-constant film by a plasma CVD method, being made of a material containing at least one of a material containing oxygen and a material containing an element reacting with oxygen, a conductor being to be buried in the first insulating film.

### CROSS-REFERENCE TO RELATED APPLICATIONS

This application is based upon and claims the benefit of priority from prior Japanese Patent Application No. 2005-050939, filed Feb. 25, 2005, the entire contents of which are incorporated herein by reference.

### BACKGROUND OF THE INVENTION

1. Field of the Invention

The present invention relates to a film forming technique which stacks an insulating film around an interconnect or the like, and more particularly, to a method of manufacturing a semiconductor device in which strength near an interface between an interlayer insulating film which is constituted by a so-called low-relative-dielectric-constant film (low-k film) and in which an interconnect or the like is buried and another insulating film which is stacked on the interlayer insulating film and in which an interconnect or the like is buried.

2. Description of the Related Art

In recent years, with micropatterning, high integration density, speeding up, or the like of a semiconductor device, micropatterning or multi-layering of an interconnect structure in the semiconductor device is advanced, and the main stream of the internal interconnect structure has shifted from a single-layer structure to a multi-layer structure. Some semiconductor having a multi-layer interconnect structure constituted by five or more layers is also developed and produced. However, as micropatterning of an internal interconnect structure progresses, signal transmission delay based on a so-called interconnection parasitic capacitance and an interconnect resistance is posed as a problem. With multi-layering of the internal interconnect structure, signal transmission delay caused by the multi-layer interconnect structure frequently prevents a high-speed operation of the semiconductor device. At the present, various countermeasures are studied against these signal transmission delays.

In general, the signal transmission delay can be expressed by a product of an interconnection parasitic capacitance and an interconnection resistance. Therefore, in order to reduce the signal transmission delay, at least one of the interconnection parasitic capacitance and the interconnection resistance may be reduced. More specifically, in order to reduce the interconnection resistance, a technique that changes the material of an interconnect from aluminum to copper having a lower resistance is examined. However, unlike formation of an aluminum interconnect, it is very difficult for a current techniques that a copper interconnect is formed by a dry etching method. For this reason, when a copper interconnect is used as an internal interconnect, a so-called buried interconnect (Damascene interconnect) structure is generally employed.

In order to reduce an interconnection parasitic capacitance, a technique that applies a so-called low-relative-dielectric-constant film to an interlayer insulating film in place of a general insulating film is tried. Such a technique is described in, for example, Japanese Patent No. 3436221. The technique is also described in H. Kudo et al., “Copper Dual Damascene Interconnects with Very Low-k Dielectrics Targeting for 130 nm Node”, Proceeding of the IEEE 2000 International Interconnect Technology Conference, pp. 270 to 272, 2000, (San Francisco, Calif., USA) or the like. More specifically, a technique is examined that applies an SiOF film formed by a CVD method, a so-called SOG (Spin on Glass) film formed by a spin coat method, an organic resin film made of a polymer, etc., or the like to an interlayer insulating film in place of a silicon oxide film made of an SiO₂ or the like and formed by a CVD method.

For example, although the relative dielectric constant of a general SiO₂ film is 3.9, the relative dielectric constant of an SiOF film can be lowered to about 3.4. However, from a viewpoint of stability of the film, it is very difficult for practical use that the relative dielectric constant of the SiOF film is lowered to about 3.4. In contrast to this, the relative dielectric constant of a low-relative-dielectric-constant coating film formed by a coating method such as a spin coat method can be lowered to about 2.0. For this reason, a study to apply the low-relative-dielectric-constant coating film to an interlayer insulating film is powerfully advanced at the present.

In this case, as a typical method of forming a buried interconnect, an example in which an upper-layer interconnect is formed as a buried interconnect on an underlying film in which a buried interconnect serving as a lower-layer interconnect is formed in advance will be briefly described below. It is assumed that a low-relative-dielectric-constant film is used as an interlayer insulating film.

First, an etching stopper film is formed on an underlying film in which a buried interconnect serving as a lower-layer interconnect is formed in advance. Then, an interlayer insulating film composed of a low-relative-dielectric-constant film is formed on the etching stopper film. Subsequently, a cap film is formed on the interlayer insulating film. A resist mask film for forming a via hole is formed on the cap film. Subsequently, a via hole is formed in the inside of the resist mask film for forming a via hole, the cap film and the interlayer insulating film by etching. Thereafter, the resist mask film for forming a via hole is removed.

Next, a resist mask film for forming an interconnect groove is formed on the cap film having the via hole formed therein. Then, an interconnect groove is formed in the inside of the resist mask film for forming an interconnect groove. An interconnect groove is formed in the inside of the cap film and the interlayer insulating film by etching. Subsequently, the via hole is further dug down by etching to open the etching stopper film, so as to expose the surface of the lower-layer interconnect. Thereafter, the resist mask film for forming an interconnect groove is removed.

Next, a barrier metal film and a seed Cu film serving as the underlying film of the upper-layer interconnect are continuously formed in the via hole and the interconnect groove. Subsequently, a Cu film serving as a main body of the upper-layer interconnect is formed on the seed Cu film by a plating method to bury the via hole and the interconnect groove with the barrier metal film and the Cu film. Finally, the surface of the cap film is polished by a CMP method to flatten the surface. In this manner, the buried Cu interconnect serving as an upper-layer interconnect is formed on an the underlying film in which the buried interconnect serving as the lower-layer interconnect is formed in advance.

In the step of forming the upper-layer interconnect described above, a low-relative-dielectric-constant film containing a methyl radical (—CH₃) in SiO₂ is generally used as the low-relative-dielectric-constant film serving as the interlayer insulating film. Accordingly, as the cap film, an SiO₂ film is generally used. The cap film is generally formed by a plasma CVD method using TEOS/O₂ or SiH₄/N₂O as a source gas. In such a case, a plasma containing oxygen (O) generated when the cap film is formed oxidizes the surface part of the low-relative-dielectric-constant interlayer insulating film serving as the underlying film. At this time, an organic component is removed from the inside of the interlayer insulating film to form a damage layer in the surface part of the interlayer insulating film. The damage layer is brittler than the other parts of the interlayer insulating film. After the cap film is formed, the damage layer serves as a brittle layer near the interface between the cap film and the low-relative-dielectric-constant interlayer insulating film. As a result, when a CMP method is performed on the surface of the cap film (SiO₂), the possibility of peeling a film near the interface between the cap film and the low-relative-dielectric-constant interlayer insulating film becomes very high.

### BRIEF SUMMARY OF THE INVENTION

According to an aspect of the invention, there is provided a manufacturing method of a semiconductor device, comprising: providing a low-relative-dielectric-constant film above a substrate, the low-relative-dielectric-constant film containing at least oxygen (O) and having a relative dielectric constant of 3.3 or more, a conductor being to be buried in the low-relative-dielectric-constant film; performing a plasma processing by discharging a gas containing a noble gas as a main component to the low-relative-dielectric-constant film, the plasma processing being executed while the substrate above which the low-relative-dielectric-constant film is provided is storing in a processing chamber having an inside covered with a material composed of an element except for oxygen and substantially set under an oxygen-free atmosphere; and providing a first insulating film above the low-relative-dielectric-constant film by a plasma CVD method, the first insulating film being made of a material containing at least one of a material containing oxygen and a material containing an element reacting with oxygen, a conductor being to be buried in the first insulating film.

According to another aspect of the invention, there is provided a manufacturing method of a semiconductor device, comprising: providing a first low-relative-dielectric-constant film above a substrate, the first low-relative-dielectric-constant film containing at least oxygen (O), and having a relative dielectric constant of 3.3 or less, a conductor being to be buried in the first low-relative-dielectric-constant film; providing a second low-relative-dielectric-constant film on the first low-relative-dielectric-constant film, the second low-relative-dielectric-constant film containing at least oxygen (O), having a relative dielectric constant of 3.3 or less and having a film density higher than that of the first low-relative-dielectric-constant film, a conductor being to be buried in the second low-relative-dielectric-constant film; and irradiating an electron beam on at least the first and second low-relative-dielectric-constant films.

### BRIEF DESCRIPTION OF THE SEVERAL VIEWS OF THE DRAWING

FIGS. 1A to 1E are process sectional views showing a method of manufacturing a semiconductor device according to a first embodiment;

FIGS. 2A to 2D are process sectional views subsequent to FIG. 1E, showing the method of manufacturing a semiconductor device according to the first embodiment;

FIGS. 3A to 3D are process sectional views subsequent to FIG. 2D, showing the method of manufacturing a semiconductor device according to the first embodiment;

FIG. 4 is a sectional view simplistically showing an apparatus for manufacturing a semiconductor device according to the first embodiment;

FIGS. 5A to 5D are process sectional views showing a method of manufacturing a semiconductor device according to a second embodiment;

FIGS. 6A to 6D are process sectional views showing a method of manufacturing a semiconductor device according to a third embodiment;

FIGS. 7A to 7D are process sectional views subsequent to FIG. 6D, showing the method of manufacturing a semiconductor device according to the third embodiment;

FIGS. 8A to 8D are process sectional views subsequent to FIG. 7D, showing the method of manufacturing a semiconductor device according to the third embodiment; and

FIG. 9 is a sectional view showing a semiconductor device serving as a comparative example to the first embodiment.

### DETAILED DESCRIPTION OF THE INVENTION

Embodiments according to the present invention will be described below with reference to the accompanying drawings.

### First Embodiment

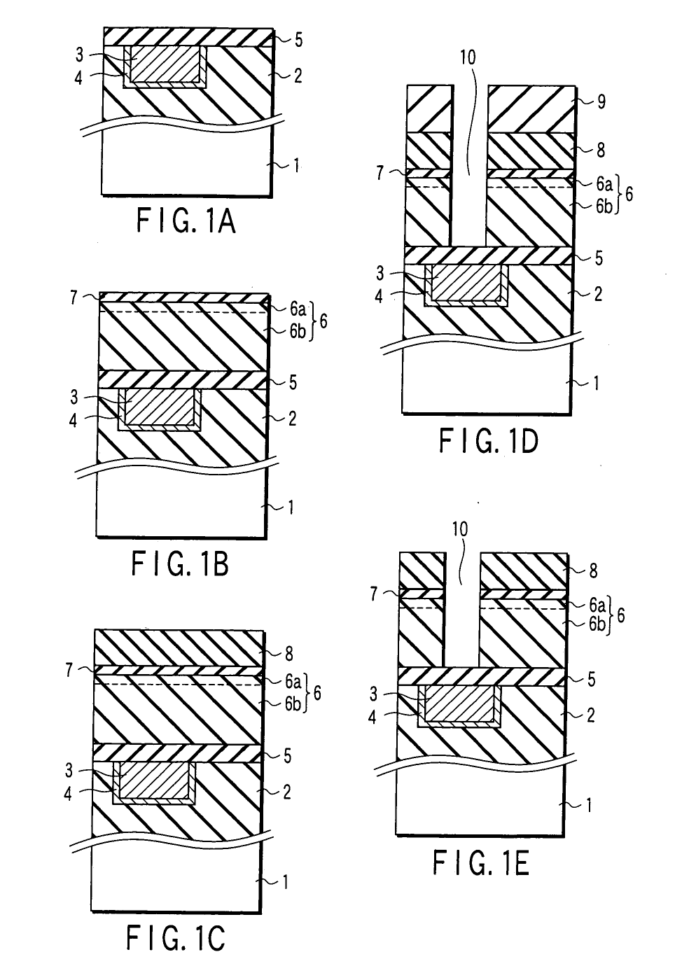

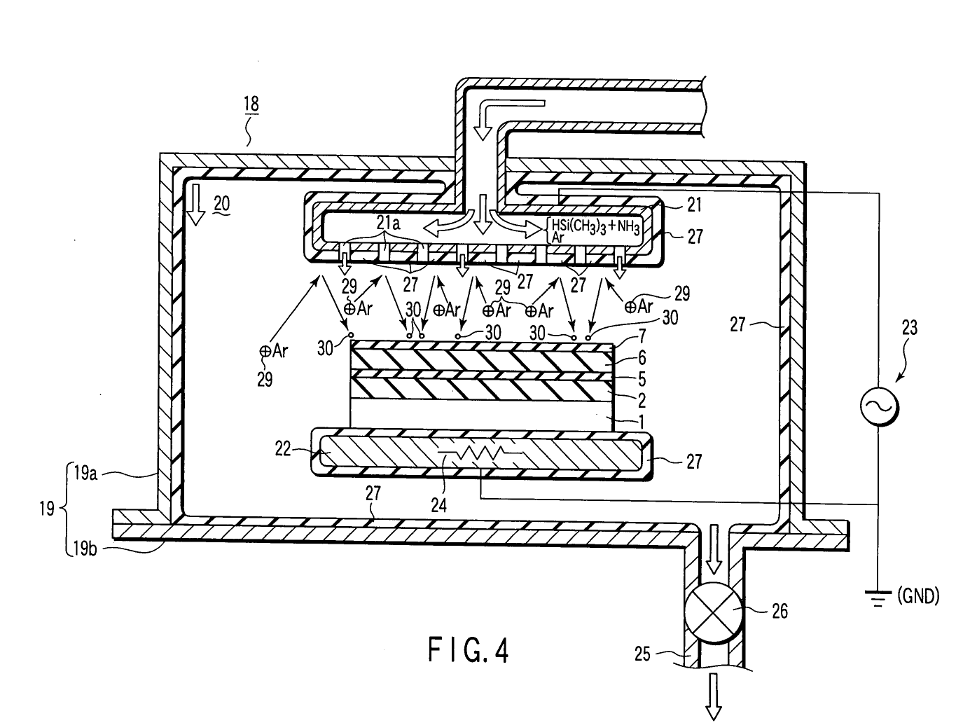

A first embodiment according to the present invention will be described below in detail with reference to FIGS. 1A to 1E, FIGS. 2A to 2D, FIGS. 3A to 3D, and FIG. 4. FIGS. 1A to 3D are process sectional views showing a method of manufacturing a semiconductor device according to the embodiment. FIG. 4 is a sectional view simplistically showing an apparatus for manufacturing a semiconductor device according to the embodiment.

As shown in FIG. 1A, an n-th (n is an integer which is 1 or more) insulating film (interlayer insulating film) 2 is arranged on a semiconductor substrate (wafer) 1 on which an element isolation region (not shown), various semiconductor elements, and the like are formed. The n-th interlayer insulating film (inter-level dielectrics: ILD) 2, like an (n+1)th interlayer insulating film 6 to be described later, may be constituted by a so-called low-relative-dielectric-constant film (low-k film). More specifically, the n-th interlayer insulating film 2 may be constituted by an SiCO:H film. In a surface part of the n-th interlayer insulating film 2, a lower-layer interconnect 3 made of, for example, Cu is buried. At the same time, a barrier metal film 4 made of, for example, TaN is buried in the surface part of the n-th interlayer insulating film 2 to cover the lower-layer interconnect 3. Subsequently, a predetermined film-forming process, an etching process, and the like are performed to form the (n+1)th interlayer insulating film 6 constituted by a low-relative-dielectric-constant film is arranged on the n-th interlayer insulating film 2, and an upper-layer interconnect 15 which is electrically connected to the lower-layer interconnect 3 is buried in the (n+1)th interlayer insulating film 6.

First, as shown in FIG. 1A, an SiCN:H film 5 is formed on the surface of the n-th interlayer insulating film 2 by a plasma CVD method to cover the surfaces (exposed surfaces) of the lower-layer interconnect 3 and the barrier metal film 4. In formation of the SiCN:H film 5, a gas containing organic silane (alkylsilane) and NH₃ is used as a film-forming source (source gas). The SiCN:H film 5 is deposited on the interlayer insulating film 2 until the SiCN:H film 5 has a thickness of about 50 nm. The SiCN:H film 5 serves as an etching stopper film to prevent the lower-layer interconnect 3 from being etched by overetching in formation of a via hole 10 to be described later.

Next, as shown in FIG. 1B, an SiCO:H film 6 serving as the (n+1)th interlayer insulating film is formed on the surface of the SiCN:H film 5 by a plasma CVD method. In formation of the SiCO:H film 6, a gas containing organic silane having a cyclic structure and O₂ is used as a source gas. A film forming temperature (substrate temperature) in formation of the SiCO:H film 6 is set at about 350° C. The SiCO:H film 6 is deposited on the SiCN:H film 5 until the SiCO:H film 6 has a thickness of about 350 nm. The SiCO:H film 6 is a so-called low-relative-dielectric-constant film (low-k film) and also called a low-relative-dielectric-constant interlayer insulating film. The relative dielectric constant of the SiCO:H film 6 is reduced to about 2.5 although the relative dielectric constant of a silicon dioxide film (SiO₂ film) serving as a general interlayer insulating film is about 4.0. Subsequently, a second insulating film 7 constituted by an element except for oxygen is formed on the surface of the SiCO:H film 6 prior to formation of a first insulating film 8 to be described later. More specifically, an SiCN:H film 7 serving as the second insulating film is formed on the surface of the SiCO:H film 6 prior to formation of an SiO₂ film 8 serving as the first insulating film.

In the embodiment, the SiCN:H film 7 is formed by a plasma process like the SiCN:H film 5 or the SiCO:H film 6. However, the SiCN:H film 7 is formed by a film forming method (processing method) different from that of the SiCN:H film 5 or the SiCO:H film 6 in a processing chamber different from a processing chamber (reaction vessel) (not shown) in which the SiCN:H film 5 or the SiCO:H film 6 is formed. The semiconductor substrate 1 having the SiCO:H film 6 arranged thereon is held under an oxygen-free atmosphere until the formation of the SiCN:H film 7 is finished such that the surface part of the SiCO:H film 6 is prevented from being oxidized by oxygen (O) and deteriorated in film quality. More specifically, the semiconductor substrate 1 having the SiCO:H film 6 arranged thereon is held under an atmosphere which is not in contact with atmospheric air or the like until the formation of the SiCN:H film 7 is finished such that a brittle layer is prevented from being formed on the surface part of the SiCO:H film 6. The step of forming the SiCN:H film 7 will be described below in detail.

First, with reference to FIG. 4, a semiconductor device manufacturing apparatus 18 according to the embodiment to form the SiCN:H film 7 will be described below. The semiconductor device manufacturing apparatus 18 is a plasma CVD apparatus which is a kind of a film forming apparatus. More specifically, the SiCN:H film 7 is formed by a plasma CVD method. The plasma CVD method for use in formation of the SiCN:H film 7 is different from a general plasma CVD method used when the SiCN:H film 5 or the SiCO:H film 6 is formed.

As shown in FIG. 4, the plasma CVD apparatus 18 includes a apparatus main body 19 constituted by an upper main body 19a and a lower main body 19b. The upper main body 19a constitutes a lid and a side wall of the apparatus main body 19. The lower main body 19b constitutes a bottom of the apparatus main body 19. The apparatus main body 19 is also called a reaction vessel, a vacuum vessel (bell jar), a chamber, or the like. The interior of the apparatus main body 19 serves as a processing chamber 20 in which the semiconductor substrate 1 having the SiCO:H film 6 formed thereon is conveyed to be subjected to a film-forming process of the SiCN:H film 7 by a plasma CVD method.

In the processing chamber 20, an upper electrode 21 serving as a first electrode and a lower electrode 22 serving as a second electrode, both the upper electrode 21 and the lower electrode 22 having planar shapes, are arranged such that the facing surfaces are parallel to each other. Therefore, the plasma CVD apparatus 18 is also called a parallel-plate plasma CVD apparatus. The upper electrode 21 is electrically connected to a high-frequency power supply (AC power supply) 23 through a rectifier (not shown). In contrast to this, the lower electrode 22 is grounded. In this manner, a high-frequency high electric field is generated between the upper electrode 21 and the lower electrode 22 to make it possible to realize high-frequency discharge in the processing chamber 20. In the lower electrode 22, a heater 24 serving as a temperature adjuster is arranged. As will be described below, when a film-forming process is performed, the semiconductor substrate 1 placed on the lower electrode 22 is heated by the heater 24 such that the substrate temperature becomes an appropriate film forming temperature and is kept.

As shown in FIG. 4, the upper electrode 21 is formed in a hollow shape such that a gas can flow therein. Herewith, the upper electrode 21 penetrates the upper main body 19a, extends from the inside of the processing chamber 20 to the outside thereof, and is connected to a gals supply device (not shown) arranged outside the processing chamber 20. On a surface of the upper electrode 21, the surface opposing the lower electrode 22, a plurality of air-supply holes 21a to introduce a gas supplied from the gas supply device into the interior of the processing chamber 20 through the inside of the upper electrode 21 are formed as an outline arrow in FIG. 4. In this manner, the upper electrode 21 also functions as an air-supply pipe (air-supply nozzle or dispersal nozzle) to supply a predetermined gas into the processing chamber 20. For example, a source gas (reaction gas) of the SiCN:H film 7 is introduced into the inside of the processing chamber 20 through the upper electrode 21. Herewith, a source gas of plasma ions (plasma gas) for use in a film-forming process of the SiCN:H film 7 by the plasma CVD method is introduced into the processing chamber 20 through the upper electrode 21.

As shown in FIG. 4, an exhaust pipe (exhaust nozzle) 25 to discharge (exhaust) a gas unnecessary for a film-forming process of the SiCN:H film 7 from the inside of the processing chamber 20 to the outside thereof is arranged on the lower main body 19b. In the exhaust pipe 25, a pressure-regulating valve 26 serving as a pressure-regulating device to set a pressure in the processing chamber 20 at a desired pressure is arranged. Furthermore, although not shown, a vacuum pump serving as an exhaust device (suction device) to suck the gas in the processing chamber 20 out of the processing chamber 20 is arranged outside the processing chamber 20. The exhaust pipe 25 is connected to the vacuum pump through the pressure-regulating valve 26. Air present in the processing chamber 20 or excessive source gases or the like which do not contribute to the film-forming process of the SiCN:H film 7 are exhausted out of the processing chamber 20 through the exhaust pipe 25, the pressure-regulating valve 26, and the vacuum pump prior to the film-forming process of the SiCN:H film 7 as indicated by a bold-line arrow in FIG. 4.

Next, with reference to FIGS. 4 and 1B, a method of forming the SiCN:H film 7 by using the plasma CVD apparatus 18 will be described below. In the embodiment, as shown in FIG. 4, the inside of the processing chamber 20 is almost entirely covered with a material 27 constituted by an element consisting of an element except for oxygen prior to the film-forming process of the SiCN:H film 7 in the processing chamber 20. More specifically, before the semiconductor substrate 1 having the SiCO:H film 6 formed thereon is conveyed (arranged) into the processing chamber 20, the precoat film 27 made of SiCN:H serving as the same material as that of the second insulating film 7 is almost entirely coated on the inside of the processing chamber 20. The inside of the processing chamber 20 includes not only the inner wall surface of the processing chamber 20 but also the surfaces or the like of the upper and lower electrodes 21 and 22. In this case, prior to explanation about the method of forming the SiCN:H film 7, a coating method for the precoat film (SiCN:H film) 27 will be described below.

First, as described above, in order to prevent the SiCO:H film 6 from being in contact with oxygen until the film-forming process of the SiCN:H film 7 is finished, as indicated by a bold-line arrow in FIG. 4, air or the like present in the processing chamber 20 are exhausted out of the processing chamber 20 through the exhaust pipe 25, the pressure-regulating valve 26, and the vacuum pump in advance before the semiconductor substrate 1 having the SiCO:H film 6 formed thereon is conveyed into the processing chamber 20. In this manner, prior to the coating of the material 27, the inside of the processing chamber 20 is set in a high-vacuum state in which oxygen is rarely present.

Subsequently, as indicated by an outline arrow in FIG. 4, a material of the material 27 is introduced into the processing chamber 20 through the air-supply holes 21a of the air-supply nozzle (upper electrode) 21. In the embodiment, as described above, the precoat film 27 is constituted by an SiCN:H film as in the second insulating film 7. For this reason, the same material as that of the second insulating film 7 is used as the material of the precoat film 27. In order to keep the state in which oxygen is rarely present inside the processing chamber 20, a material constituted by an element except for oxygen is used as the material of the precoat film 27. More specifically, a gas mixture of organic silane such as gaseous trimethyl silane (HSi(CH₃)₃) and ammonia (NH₃) is used as the material of the precoat film 27. The trimethyl silane gas and the ammonia gas are introduced into the processing chamber 20 at a mixture ratio of about 3:1. When predetermined amounts of trimethyl silane gas and ammonia gas are introduced into the processing chamber 20, the supply of the trimethyl silane gas and the ammonia gas in the processing chamber 20 is stopped. Thereafter, the pressure-regulating valve 26, the vacuum pump, and the like are operated to set a pressure and a temperature in the processing chamber 20 at predetermined values, respectively.

Subsequently, a high-frequency voltage of about 13.56 MHz is applied to the upper electrode 21 by using the high-frequency power supply 23. In this manner, a high-frequency high electric field is generated between the upper electrode 21 and the lower electrode 22 to realize high-frequency discharge in the processing chamber 20. The gas mixture of the trimethyl silane gas and the ammonia gas in the processing chamber 20 is set in a plasma state by the high-frequency discharge to cause various plasma ions contained in the plasma gas to react each other. In this manner, SiCN:H molecules are generated in the processing chamber 20, and the generated SiCN:H molecules begin to adhere to the inner side of the processing chamber 20. More specifically, the SiCN:H film 27 serving as a precoat film begins to be formed in the processing chamber 20.

When SiCN:H film 27 almost entirely adheres to the inner side of the processing chamber 20, and when the film thickness of the adhered SiCN:H film 27 reaches a predetermined desired thickness, application of a high-frequency voltage to the upper electrode 21 is stopped. In this manner, the gas mixture (atmosphere) of the trimethyl silane gas and the ammonia gas in the processing chamber 20 is released from the plasma state to end the film-forming process of the SiCN:H film 27. More specifically, the precoating in the processing chamber 20 is ended. Thereafter, as indicated by a bold-line arrow in FIG. 4, the gas mixture of the trimethyl silane gas and the ammonia gas remaining in the processing chamber 20, excessive SiCN:H molecules, and the like are sucked out of the processing chamber 20 by the exhaust pipe 25, the pressure-regulating valve 26, and the vacuum pump and exhausted out of the processing chamber 20.

With the steps up to now, the inside of the processing chamber 20, including the surfaces or the like of the upper and lower electrodes 21 and 22, is almost entirely coated with the SiCN:H film 27. Thereafter, the semiconductor substrate 1 having the SiCO:H film 6 formed thereon is conveyed (arranged) into the processing chamber 20 to start film formation of the second insulating film 7 serving as the second insulating film.

Next, a method of forming the second insulating film 7 will be described below. The semiconductor substrate 1 having the SiCO:H film 6 formed thereon is conveyed into the processing chamber 20 of the plasma CVD apparatus 18 coated with the precoat film (SiCN:H film) 27 while keeping the SiCO:H film 6 free from oxygen. More specifically, the semiconductor substrate 1 having the SiCO:H film 6 formed thereon is conveyed out of a CVD apparatus (CVD film-forming processing chamber) (not shown) in which the film-forming process of the SiCO:H film 6 is performed without being exposed to the air (atmosphere), and the semiconductor substrate 1 is conveyed into the processing chamber 20 coated with the precoat film 27. At this time, the inside of the processing chamber 20 is held in a high-vacuum state by the pressure-regulating valve 26, the vacuum pump, and the like. More specifically, the inside of the processing chamber 20 is set under an oxygen-free atmosphere in which oxygen atoms, oxygen molecules, consequently, materials containing oxygen atoms, and the like are substantially rarely present.

As shown in FIG. 4, the semiconductor substrate 1 conveyed into the processing chamber 20 is arranged between the upper electrode 21 and the lower electrode 22 serving as the counter electrode of the upper electrode 21. At this time, the semiconductor substrate 1 is placed on a major surface of the lower electrode 22 serving as a wafer-side electrode, the major surface facing the upper electrode 21, such that the SiCO:H film 6 formed on the semiconductor substrate 1 faces the upper electrode 21. Thereafter, the film-forming process of the second insulating film 7 is substantially started.

First, as indicated by an outline arrow in FIG. 4, a source gas of plasma ions (plasma gas) for use in the film-forming process (sputtering process) of the SiCN:H film 7 is introduced into the processing chamber 20 through the air-supply holes 21a of the air-supply nozzle (upper electrode) 21. In the embodiment, the material of the plasma ions for use in the film-forming process of the SiCN:H film 7, argon (Ar) that is an element of the rare gases is used. The pressure-regulating valve 26, the vacuum pump, and the like are operated to set a pressure and a temperature in the processing chamber 20 at predetermined values, respectively. After a predetermined amount of argon gas is introduced into the processing chamber 20, the high-frequency power supply 23 applies a high-frequency voltage to the upper electrode 21. In this manner, a high-frequency high electric field is generated between the upper electrode 21 and the lower electrode 22 to realize high-frequency discharge in the processing chamber 20. The argon gas in the processing chamber 20 is set in a plasma state by the high-frequency discharge to make argon atoms plasma ions. In this step, no film-forming gas is not introduced into the processing chamber 20 according to the embodiment, so that a simple film-forming phenomenon does not occur unlike in a general plasma CVD method. More specifically, in the embodiment, the SiCN:H film 7 is formed on the SiCO:H film 6 without using a simple phenomenon that deposits the thin film 7 constituted by SiCN:H on the SiCO:H film 6 by the general plasma CVD method. This will be described below in detail.

When a high-frequency high electric field is generated between the upper electrode 21 and the lower electrode 22 by a high-frequency voltage applied to the upper electrode 21 to cause high-frequency discharge in the processing chamber 20, a negative potential (voltage) called a self bias is applied to the upper electrode 21. In this case, argon atoms (argon ions: Ar⁺) 29 plasma-ionized are attracted by the upper electrode 21 while being accelerated at high speed. As a solid arrow in FIG. 4, the argon ions 29 attracted by the upper electrode 21 fastly collide with the SiCN:H film 27 deposited on the major surface of the upper electrode 21 facing the lower electrode 22, of the SiCN:H film (precoat film or coating film) 27 deposited on the surface of the upper electrode 21. In this manner, as indicated by a solid arrow in FIG. 4, SiCN:H molecules 30 are mainly beaten from the SiCN:H film 27 deposited on the major surface of the upper electrode 21 facing the lower electrode 22 (sputtered out). The SiCN:H molecules 30 sputtered from the SiCN:H film 27 begin to adhere (be deposited) to the surface of the SiCO:H film 6 on the semiconductor substrate 1 placed on the major surface of the lower electrode 22 facing the upper electrode 21 again. More specifically, film formation of the SiCN:H film 7 serving as the second insulating film is started. In the embodiment, a film forming temperature at which the SiCN:H film 7 on the SiCO:H film 6 is formed is set at about 350° C. which is equal to the film forming temperature used when the SiCO:H film 6 is formed on the semiconductor substrate 1. A substrate temperature of the semiconductor substrate 1 when the SiCN:H film 7 is formed on the SiCO:H film 6 is also set at about 350° C. by the heater 24 built in the lower electrode 22.

As shown in FIG. 1B, the SiCN:H film 7 is deposited on the surface of the SiCO:H film 6 until the film thickness of the SiCN:H film 7 is about 2 nm. When the film thickness of the SiCN:H film 7 reaches about 2 nm, application of the high-frequency voltage to the upper electrode 21 is stopped. In this manner, the argon gas (atmosphere) in the processing chamber 20 is released from a plasma state to end the film-forming process of the SiCN:H film 7. Upon completion of the film-forming process of the SiCN:H film 7, an argon gas remaining in the processing chamber 20 is sucked out of the processing chamber 20 by the exhaust pipe 25, the pressure-regulating valve 26, and the vacuum pump and exhausted out of the processing chamber 20, as indicated by a bold-line arrow in FIG. 4.

The SiCN:H film 7 on the SiCO:H film 6 serves as a so-called sacrifice film (barrier film) to suppress the SiCO:H film 6 from being oxidized when the SiO₂ film 8 serving as the first insulating film (to be described later) is formed on the SiCN:H film 7. According to an experiment executed by the present inventors, it has been found that the probability of eliminating the SiCN:H film 7 is high when the SiO₂ film 8 is formed because the SiCN:H film 7 is very thin, i.e., about 2 nm. As shown in FIG. 1C, it has been understood that, when the SiCN:H film 7 is very thickly formed, the SiCN:H film 7 remained between the SiCO:H film 6 and the SiO₂ film 8 even after the SiO₂ film 8 is formed above the SiCO:H film 6.

In the SiCN:H film 7, the barrier function that suppresses the SiCO:H film 6 from being oxidized is improved as the thickness of the SiCN:H film 7 increases. Therefore, the SiCN:H film 7 easily achieves its object when the thickness of the SiCN:H film 7 increases. However, the SiCN:H film 7 is a general insulating film having a low relative dielectric constant unlike the SiCO:H film 6 which is a low-relative-dielectric-constant interlayer insulating film. As the thickness of the SiCN:H film 7 increases, it is difficult to achieve a high-speed operation of a semiconductor device by employing the SiCO:H film 6 as a member occupying a large part of the interlayer insulating film. With respect to both the effects having the trade-off relation, the present inventors have further executed an experiment to find a thickness of the SiCN:H film 7 at which the effects are compatible at a high level in a balanced manner. As a result, it has been understood that the thickness of the SiCN:H film 7 is preferably about 5 nm or less. More specifically, according to the experiment executed by the present inventors, it has been understood that, when the thickness of the SiCN:H film 7 is about 5 nm or less, the oxidization suppressing function of the SiCO:H film 6 and the high-speed operation of the semiconductor device can be compatible at a high level in a balanced manner.

The SiCO:H film 6 which is a low-relative-dielectric-constant insulating film is a porous insulating film and has a film density lower than that of the SiCN:H film 7 which is a normal insulating film. For this reason, the SiCO:H film 6 also has a mechanical strength (physical strength) lower than that of the SiCN:H film 7. However, as described above, in the embodiment, a plasma processing by the argon ions 29 is performed to the surface part of the SiCO:H film 6 under an atmosphere from which oxygen ions an d the like are substantially excluded, in the step of forming the SiCN:H film 7 on the SiCO:H film 6. In this manner, the surface part of the SiCO:H film 6 is densified (density-grown) in comparison with a part except for the surface part. More specifically, as shown in FIG. 1B, when the SiCN:H film 7 is formed on the SiCO:H film 6, a dense layer 6a is also formed on the surface part of the SiCO:H film 6 by a plasma processing. More specifically, the SiCO:H film 6 subjected to the plasma processing, as shown in FIG. 1B, is formed as a low-relative-dielectric-constant interlayer insulating film substantially having a two-layer structure constituted by the dense layer 6a serving as the surface part and a porous layer 6b serving as a part except for the surface part, the dense layer 6a and the porous layer 6b being different in film quality.

Next, as shown in FIG. 1C, the first insulating film 8 made of at least one material of a material containing oxygen and a material containing an element reacting oxygen is formed on the surface of the SiCN:H film 7 serving as the second insulating film. More specifically, the SiO₂ film 8 serving as the first insulating film is formed on the surface of the SiCN:H film 7 by a normal plasma CVD method. The SiO₂ film 8 is deposited on the SiCN:H film 7 until the thickness of the SiO₂ film 8 becomes about 100 nm. The SiO₂ film 8 serves as a so-called cap film to the SiCO:H film 6 serving as an interlayer insulating film. In formation of the SiO₂ film 8, a gas mixture of gaseous SiH₄ and gaseous N₂O is used as a source gas.

Next, as shown in FIG. 1D, a first-recessed-part-forming resist film 9 is formed on the surface of the SiO₂ film 8. Subsequently, a pattern of a first recessed part 10 communicating with the surface of the lower-layer interconnect 3 is patterned in the resist film 9 by a photolithography method. The SiO₂ film 8, the SiCN:H film 7, and the SiCO:H film 6 are processed by a reactive ion etching (RIE) method using the patterned resist film 9 as a mask. In this manner, above the lower-layer interconnect 3, the first recessed part 10 which penetrates the resist film 9, the SiO₂ film 8, the SiCN:H film 7, and the SiCO:H film 6 and which has a predetermined pattern is formed. As described above, the SiCN:H film 5 serving as an etching stopper film and covering the surface of the lower-layer interconnect 3 is formed between the SiCO:H film 6 and the lower-layer interconnect 3. For this reason, in the etching step, the first recessed part 10 is formed in such a depth that the lower end of the first recessed part 10 exposes the surface of the SiCN:H film 5.

In the first recessed part 10, a plug (via plug or contact plug) 16 serving as a first conductor which is electrically connected to the lower-layer interconnect 3 as will be described later is arranged. Therefore, more specifically, the first recessed part 10 is a plug recessed part (plug groove, via hole, or contact hole) 10. Similarly, the first-recessed-part-forming resist film 9 is a plug-recessed-part-forming resist film (plug-groove-forming resist film, via-hole-forming resist film, or a contact-hole-forming resist film) 9. In the following explanation, it is assumed that the first-recessed-part-forming resist film 9, the first recessed part 10, and the first conductor 16 are called a via-hole-forming resist film 9, a via hole 10, and a via plug 16, respectively.

Next, as shown in FIG. 1E, the via-hole-forming resist film 9 is peeled and removed by using an electrically discharged O₂ gas from the surface of the SiO₂ film 8 having the via hole 10 formed therein.

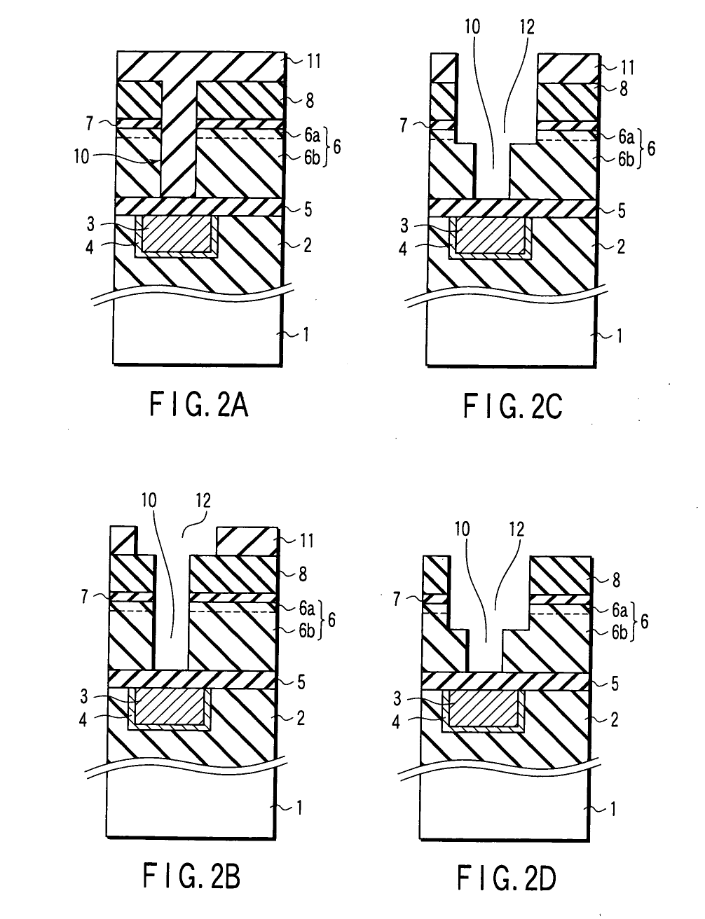

Next, as shown in FIG. 2A, a second-recessed-part-forming resist film 11 is formed on the inside of the via hole 10 and the SiO₂ film 8 having the via hole 10 formed therein.

Next, as shown in FIG. 2B, a pattern of a second recessed part 12 communicating with the via hole 10 is patterned in the resist film 11 by a photolithography method.

As shown in FIG. 2C, the SiO₂ film 8, the SiCN:H film 7, and the SiCO:H film 6 are processed by an RIE method using the patterned resist film 11 as a mask. In this manner, the second recessed part 12 having a predetermined pattern is formed in the second-recessed-part-forming resist film 11, the SiO₂ film 8, the SiCN:H film 7, and the SiCO:H film 6 above the lower-layer interconnect 3 to communicate with the via hole 10. The second recessed part 12 is formed in such a depth that the lower end of the second recessed part 12 is located at an intermediate part of the SiCO:H film 6.

In the second recessed part 12, an interconnect (upper-layer interconnect) 15 serving as a second conductor which is electrically connected to the lower-layer interconnect 3 through the via plug 16 as will be described later is arranged. Therefore, the second recessed part 12 is specifically an interconnect recessed part (interconnect groove, upper-layer interconnect recessed part, or upper-layer interconnect groove) 12. Similarly, the second-recessed-part-forming resist film 11 is specifically an interconnect-recessed-part-forming resist film (interconnect-groove-forming resist film, upper-layer-interconnect-recessed-part-forming resist film, or upper-layer-interconnect-groove-forming resist film) 11. In the following explanation, it is assumed that the second-recessed-part-forming resist film 11, the second recessed part 12, and the second conductor 15 are simply called an upper-layer-interconnect-recessed-part-forming resist film 11, an upper-layer interconnect recessed part 12, and an upper-layer interconnect 15, respectively.

Next, as shown in FIG. 2D, the upper-layer-interconnect-recessed-part-forming resist film 11 is peeled and removed by using an electrically discharged O₂ gas from the surface of the SiO₂ film 8 having the upper-layer interconnect recessed part 12 formed therein.

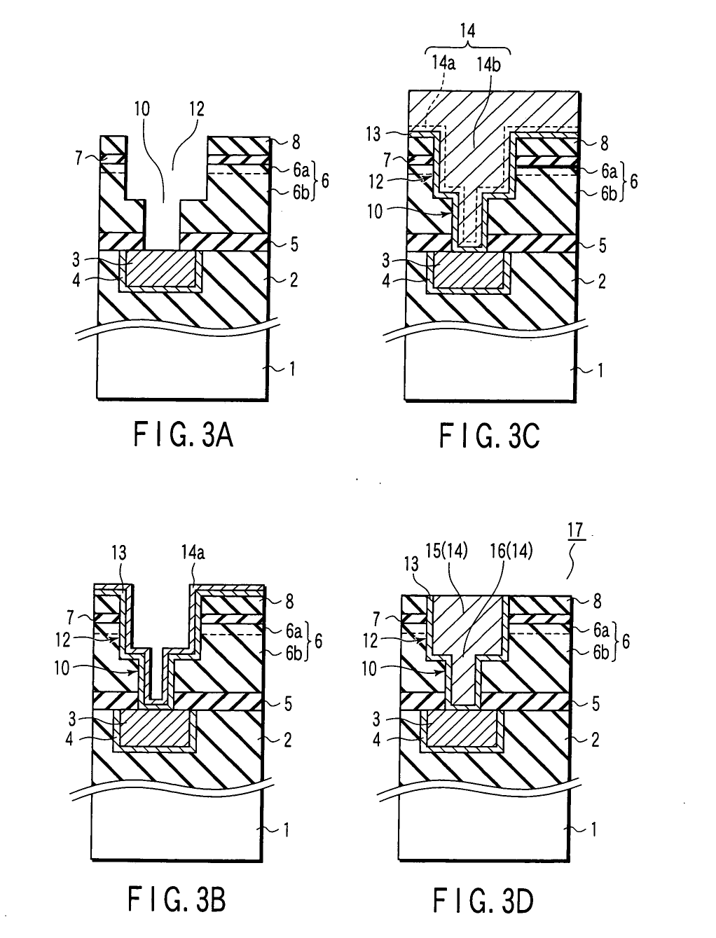

Next, as shown in FIG. 3A, the SiCN:H film 5 is processed by an RIE method until the via hole 10 penetrates the SiCN:H film 5 forming the bottom of the via hole 10. In this manner, the surface of the lower-layer interconnect 3 is exposed in the via hole 10. Accordingly, an underlayer for the via plug 16 and the upper-layer interconnect 15 which are buried in the via hole 10 and the upper-layer interconnect recessed part 12 is formed.

Next, as shown in FIG. 3B, a barrier metal film 13 is formed in the via hole 10 and the upper-layer interconnect recessed part 12 and on the SiO₂ film 8 by a sputtering method. In the embodiment, the barrier metal film 13 is made of TaN. Subsequently, an underlying layer (underlying film) 14a serving as a base for use in formation of the upper-layer interconnect 15 and the via plug 16 is formed on the surface of the TaN film 13 by the sputtering method similarly. In the embodiment, the upper-layer interconnect 15 and the via plug 16 are made of Cu. Therefore, the underlying layer 14a is made of Cu.

Next, as shown in FIG. 3C, a Cu film 14b serving as main parts of the upper-layer interconnect 15 and the via plug 16 is formed on the surface of the Cu underlying layer 14a until the via hole 10 and the upper-layer interconnect recessed part 12 are buried. More specifically, by using the underlying layer 14a as a seed layer, a Cu plating film 14b is formed on the surface of the Cu underlying layer 14a by an electrolytic plating method. At this time, the Cu seed layer (Cu underlying layer) 14a is integrated with the Cu plating film 14b to form a single Cu film 14.

Next, as shown in FIG. 3D, the TaN film 13 and the Cu film 14 on the surface of the SiO₂ film 8 are polished and removed by a chemical mechanical polishing (CMP) method. In this manner, the TaN film 13 and the Cu film 14 are buried in the via hole 10 and the upper-layer interconnect recessed part 12. As a result, the upper-layer interconnect 15 and the via plug 16 which are integrally formed by the Cu film 14 are formed in the upper-layer interconnect recessed part 12 and the via hole 10. More specifically, the upper-layer interconnect 15 and the Cu via plug 16 having so-called dual damascene structures are buried into the SiO₂ film 8, the SiCN:H film 7, the SiCO:H film 6, and the SiCN:H film 5. The Cu upper-layer interconnect 15 serving as a buried interconnect is electrically connected to the lower-layer interconnect 3 through the Cu via plug 16 and the TaN film 13. By the steps up to now, as shown in FIG. 3D, a semiconductor device 17 having a desired buried interconnect structure is obtained.

As described above, according to the first embodiment, the SiCO:H film 6 having a film density and a mechanical strength which are lower than those of a normal insulating film, as shown in FIGS. 1B to 3D, is formed as a low-relative-dielectric-constant insulating film which substantially has a two-layer structure constituted by the dense layer 6a of a surface part and the porous layer 6b of a part except for the surface part. The dense layer 6a of the surface part has a mechanical strength higher than that of the porous layer 6b. In this manner, in the semiconductor device 17 according to the embodiment, adhesiveness or strength is improved near the interface between the SiCO:H film 6 serving as the low-relative-dielectric-constant interlayer insulating film and the SiCN:H film 7 or the SiO₂ film 8 serving as another general insulating film directly or indirectly stacked on the SiCO:H film 6. As a result, in the semiconductor device 17 of the embodiment, peeling near the interface between the SiCO:H film 6 and the SiCN:H film 7 or the SiO₂ film 8 is reduced. Therefore, according to the first embodiment, the semiconductor device 17 in which peeling caused by external force does not easily occur near the interfaces among the SiCO:H film 6, the SiCN:H film 7, and the SiO₂ film 8 can be easily manufactured.

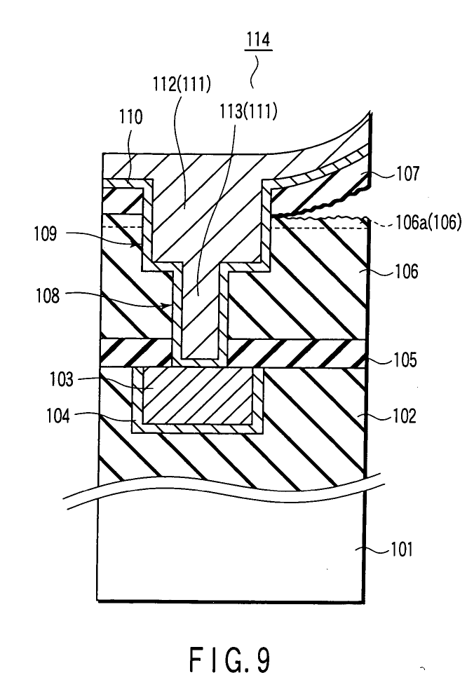

In this case, as a comparative example for the embodiment, a semiconductor device and a method of manufacturing the semiconductor device will be briefly described below with reference to FIG. 9. FIG. 9 is a sectional view showing a semiconductor device according to the comparative example for the embodiment.

As shown in FIG. 9, an interlayer insulating film 102 is formed on a semiconductor substrate 101. A lower-layer interconnect 103 and a barrier metal film 104 which covers the lower-layer interconnect 103 are buried in a surface part of the interlayer insulating film 102. Subsequently, an SiCN:H film 105 is formed on the interlayer insulating film 102 by a plasma CVD method to cover the surfaces of the lower-layer interconnect 103 and the barrier metal film 104. In formation of the SiCN:H film 105, organic silane (alkylsilane) and NH₃ are used as a source gas. Then, an SiCO:H film 106 serving as a low-relative-dielectric-constant interlayer insulating film is formed on the SiCN:H film 105 by a plasma CVD method. In formation of the SiCO:H film 106, organic silane such as alkylsilane or organic silane having a cyclic structure and O₂ are used as a source gas. An SiO₂ film 107 is formed on the SiCO:H film 106 by a plasma CVD method. In formation of the SiO₂ film 107, SiH₄+N₂O is used as a source gas.

Subsequently, the SiO₂ film 107 and the SiCO:H film 106 are processed by a normal photolithograhy method or a reactive ion etching (RIE) method to form a via hole 108 in the SiO₂ film 107 and the SiCO:H film 106 above the lower-layer interconnect 103. Subsequently, the SiO₂ film 107 and the SiCO:H film 106 are processed by the normal photolithography method or the RIE method to form an interconnect groove 109 communicating with the via hole 108 in the films 106 and 107. Then, the SiCN:H film 105 is processed by an RIE method until the via hole 108 penetrates the SiCN:H film 105 forming the bottom of the via hole 108 to expose the surface of the lower-layer interconnect 103.

Subsequently, a barrier metal film 110 is formed in the via hole 108 and the interconnect groove 109 and on the SiO₂ film 107. A Cu film 111 is formed on the barrier metal film 110 until the via hole 108 and the interconnect groove 109 are buried. Subsequently, the barrier metal film 110 and the Cu film 111 on the SiO₂ film 107 are removed by a chemical mechanical polishing (CMP) method, and the barrier metal film 110 and the Cu film 111 are buried in the via hole 108 and the interconnect groove 109. As a result, an upper-layer interconnect 112 and a via plug 113 integrally formed by the Cu film 111 are electrically connected to the lower-layer interconnect 103 through the barrier metal film 110 and formed in the via hole 108 and the interconnect groove 109. More specifically, a semiconductor device 114 is obtained which has a buried interconnect structure in which the Cu upper-layer interconnect 112 constituted by a so-called dual damascene structure is buried in the SiO₂ film 107, the SiCO:H film 106, and the SiCN:H film 105.

However, according to an experiment executed by the present inventors, it has been found that peeling occurs at a very high ratio on the interface between the SiO₂ film 107 and the SiCO:H film 106 in a CMP method to manufacture the semiconductor device 114 by the manufacturing method as shown in FIG. 9. As a result of study committedly executed by the present inventors, it has been found that the peeling on the interface between the SiO₂ film 107 and the SiCO:H film 106 occurs due to the following reason.

According to the manufacturing method, the SiO₂ film 107 is formed on the SiCO:H film 106 by a plasma CVD method. In this case, it has been found that the surface part of the SiCO:H film 106 serving as an underlying film of the SiO₂ film 107 is oxidized by O₂ gas (oxygen plasma ions) to cause a chemical reaction expressed by the following chemical equation:
≡S₁—CH₃+2O₂→≡Si—OH+CO₂+H₂O (1)

In this chemical equation (1), ≡S₁—CH₃ denotes a methyl radical contained in the SiCO:H film 106. The ≡Si—OH radical generated by the chemical reaction functions as a so-called moisture-absorption site which adsorbs moisture (H₂O). By the ≡Si—OH radical, a brittle layer 106a which adsorbs moisture (H₂O) is formed on the surface part of the SiCO:H film 106 serving as the interface between the SiCO:H film 106 of the lower-layer film and the SiO₂ film 107 of the upper layer film as shown in FIG. 9. The brittle layer 106a is brittler than another part of the SiCO:H film 106 and has a low mechanical strength (physical strength). More specifically, the brittle layer 106a has a resistance to external stress which is lower than that of another part of the SiCO:H film 106. For this reason, in the CMP step which is a post-process of the step of forming the SiO₂ film 107, the brittle layer 106a serving as the interface between the SiCO:H film 106 and the SiO₂ film 107 suffers stress, peeling easily occurs between the SiCO:H film 106 and the SiO₂ film 107 as shown in FIG. 9.

When the peeling occurs between the brittle layer 106a and the SiO₂ film 107, the subsequent CMP step cannot be actually continued. More specifically, the buried interconnect structure constituted by the Cu upper-layer interconnect 112 and the Cu via plug 113 cannot be actually realized. Consequently, the semiconductor device 114 cannot be actually manufactured. Even though the CMP step is continued to make it possible to realize the buried interconnect structure constituted by the upper-layer interconnect 112 and the Cu via plug 113, deterioration of the SiCO:H film 106, the SiO₂ film 107, the barrier metal film 110, the Cu upper-layer interconnect 112, the Cu via plug 113, and the like is easily started from a position where peeling occurs. Such a phenomenon is especially conspicuous when Cu which is easily oxidized (corroded) is used as the material of the interconnect or the via plug.

In this manner, when peeling occurs near the interlayer insulating film 106, the buried interconnect structure is deteriorated in quality and reliability. Consequently, the semiconductor device 114 is deteriorated in quality, reliability, performance, and the like as a whole. The semiconductor device 114 is hard to sufficiently and appropriately exert the desired functions. Therefore, the semiconductor device 114 in which peeling occurs near the interlayer insulating film 106 is regarded as a defective product, so that the semiconductor device 114 cannot be shipped to the market. More specifically, the yield and productive efficiency of the semiconductor device 114 are down.

In comparison with the semiconductor device 114 and the method of manufacturing the semiconductor device which are described as the comparative example, the semiconductor device 17 according to the first embodiment of the present invention and the method of manufacturing the same have the many advantages described below. The advantages will be described below in detail.

First, in the embodiment, as described above, the SiCO:H film 6 which is a low-relative-dielectric-constant interlayer insulating film, and the SiCN:H film 7 and the SiO₂ film 8 which are normal insulating films formed on the SiCO:H film 6 are not continuously formed in the same reaction vessel (film-forming device). And, the semiconductor substrate 1 having the SiCO:H film 6 formed thereon is kept from being in contact with oxygen until the formation of the SiCN:H film 7 on the SiCO:H film 6 is finished. Prior to the formation of the SiCN:H film 7 on the SiCO:H film 6, the inside of the reaction vessel 19 for forming the SiCN:H film 7 is almost entirely coated with the oxygen-free precoat film (SiCN:H film) 27. In this manner, the risk that oxygen is inserted from the outside of the reaction vessel 19 into the reaction vessel 19 (processing chamber 20) through a gap or the like (not shown) can be very low.

In this manner, under an oxygen-free atmosphere in which oxygen molecules (O₂) or the like are substantially absent, an oxygen-free gas containing an argon gas as a main component is plasma-discharged, and a plasma processing is performed to the SiCO:H film 6 by using the plasma argon gas. While the plasma processing using the plasma argon gas (argon ion 29) is performed to the SiCO:H film 6, the SiCN:H film 7 constituted by an element except for oxygen is formed on the SiCO:H film 6. According to the film-forming method, the risk that plasma ions (plasma O₂ gas) are generated by plasma discharge in the processing chamber 20 can be eliminated in the formation of the SiCN:H film 7. Consequently, the risk that oxygen ions produced by mixing oxygen in the plasma argon gas chemically react with the surface part of the SiCO:H film 6 can be eliminated.

The SiCN:H film 7 contains carbon atoms (C) and nitrogen atoms (N) which easily react with oxygen atoms (O). In general, when the film containing the elements which easily react with oxygen is arranged on the SiCO:H film 6 in direct contact with the SiCO:H film 6, the oxygen atoms in the SiCO:H film 6 are coupled to the carbon atoms or the nitrogen atoms to form a film which easily adsorbs moisture (H₂O) in an SiO₂ film, an SiON film, or the like on the surface part of the SiCO:H film 6. As a result, as in the semiconductor device 114 explained as the comparative example, the surface part of the SiCO:H film 6 is oxidized to form a brittle layer on the surface part of the SiCO:H film 6, and peeling or the like very easily occurs on the interface between the SiCO:H film 6 and the upper-layer film thereon. However, as described above, in the embodiment, plasma processing is performed to the SiCO:H film 6 under the atmosphere in which oxygen is substantially absent when the SiCN:H film 7 is formed on the SiCO:H film 6. In this manner, since the dense layer 6a is formed on the surface part of the SiCO:H film 6, the risk that not only the oxygen atoms in the surface part of the SiCO:H film 6 but also the oxygen atoms in the porous layer 6b are coupled to the carbon atoms or nitrogen atoms in the SiCN:H film 7 can be very low.

A low-relative-dielectric-constant insulating film is generally a porous insulating film, and has a film density lower than that of a normal insulating film. The low-relative-dielectric-constant insulating film has a mechanical strength (physical strength) lower than that of a conventional insulating film. However, in the embodiment, the dense layer 6a is, as described above, formed on the surface part of the SiCO:H film 6 serving as the low-relative-dielectric-constant insulating film. In this manner, the dense layer 6a of the SiCO:H film 6 is hard to be coupled to oxygen molecules, oxygen ions, or the like under an atmosphere around the SiCO:H film 6. More specifically, the dense layer 6a of the SiCO:H film 6 is not easily oxidized. According to an experiment executed by the present inventors, it has been found that the dense layer 6a having a thickness of about 10 nm can sufficiently suppress the porous layer 6b from being oxidized and made brittle. More specifically, it has been found that the dense layer 6a having a thickness of about 50 nm is ideal because the relative dielectric constant of the entire SiCO:H film 6 can be preferably suppressed by increasing.

According to these result, in the embodiment, the risk can be very low that, in the formation of the SiCN:H film 7, the surface part of the SiCO:H film 6 adsorbs moisture (H₂O) and is oxidized to form a brittle layer on the dense layer 6a of the SiCO:H film 6 serving as an underlying film of the SiCN:H film 7. Therefore, according to the film-forming method of the embodiment, the SiCN:H film 7 can be formed on the SiCO:H film 6 without deteriorating the film quality of the SiCO:H film 6 while performing a plasma processing to the SiCO:H film 6 having appropriate film quality. In this manner, the risk that the adhesiveness of the interface between the SiCO:H film 6 and the SiCN:H film 7 is lowered is very low.

As the material of the precoat film (SiCN:H film) 27 coating the inside of the processing chamber 20, SiCN:H which is the same as that of the SiCN:H film 7 formed inside the processing chamber 20 is used. In this manner, the risk that a material which prevents the SiCN:H film 7 having appropriate quality from being formed is generated in the processing chamber 20 can be suppressed. That is, the risk can be very low that a material which deforms or deteriorates the film quality of the SiCO:H film 6 serving as the underlying film of the SiCN:H film 7 is generated in the processing chamber 20. More specifically, the risk can be very low that various contaminants including metal particles which cause metal pollution, dust or particles which cause particulate pollution, or an organic or inorganic material which does not contribute to formation of the SiCN:H film 7 are generated by plasma discharge from the apparatus main body (reaction vessel) 19 or the like surrounding the processing chamber 20.

According to the embodiment, not only the inner wall surface of the processing chamber 20 but also the surfaces or the like of the upper and lower electrodes 21 and 22 are almost entirely coated with the SiCN:H film 27. As described above, the SiCN:H molecules 30 sputtered by collision of the argon ions 29 from the SiCN:H film 27 deposited on the major surface of the upper electrode 21 facing the lower electrode 22 are deposited on the surface of the SiCO:H film 6 again. In this manner, the SiCN:H film 7 is formed on the SiCO:H film 6. Such a phenomenon is the same as the phenomenon occurring in a general sputtering device (not shown). According to a normal plasma CVD method, the SiCN:H film is formed by performing electrical discharge using a gas mixture of an organic silane gas and an NH₃ gas. In this method, however, the SiCO:H film serving as the underlying film is damaged by the electrical discharge of the NH₃ gas. In this manner, the surface part of the SiCO:H film is made brittle, and defective peeling may be caused near the interlayer insulating film in a post-process of the step of forming the SiCN:H film. In contrast to this, according to the method of manufacturing a semiconductor device in the embodiment using a sputtering phenomenon with the argon ions 29, electrical discharge of the NH₃ gas or the like does not occur at all. For this reason, when the SiCN:H film 7 is formed on the SiCO:H film 6, the risk that the SiCO:H film 6 is damaged can be very low.

In this manner, according to the embodiment, the risk that the brittle film is formed on the surface part of the SiCO:H film 6 serving as the underlying film of the SiCN:H film 7 or that the film quality of the SiCO:H film 6 is deteriorated is very low to make it possible to form the SiCN:H film 7 having appropriate film quality. Consequently, the risk that the mechanical strength of the interface between the SiCO:H film 6 and the SiCN:H film 7 is lowered is very low to make it possible to improve the adhesiveness of the interface between the SiCO:H film 6 and the SiCN:H film 7.

In the embodiment, the film density of the surface part (dense layer) 6a of the SiCO:H film 6 is increased enough to be resistant to external force (stress) applied on the surface part 6a in the CMP step by a plasma processing. As a result, the mechanical strength of the dense layer 6a is improved enough to be resistant to stress applied on the dense layer 6a in the CMP step. Consequently, the adhesiveness of the interface between the dense layer 6a of the SiCO:H film 6 and the SiCN:H film 7 is improved such that peeling between the dense layer 6a and the SiCN:H film 7 is not caused by stress applied on the dense layer 6a in the CMP step. The mechanical strength of the surface part (dense layer) 6a of the SiCO:H film 6 is improved to be higher than the mechanical strength of the porous part (porous layer) 6b except for the surface part 6a of the SiCO:H film 6 having a follow film structure more than that of the surface part 6a as a matter of course.

As described above, since the dense layer 6a is formed on the surface part of the SiCO:H film 6, oxygen molecules, oxygen ions, and the like under the atmosphere around the SiCO:H film 6 can rarely reach the porous layer 6b of the SiCO:H film 6. That is, the dense layer 6a serves as a barrier layer which prevents oxygen molecules, oxygen ions, and the like from reaching the porous layer 6b. In this manner, the porous layer 6b is hard to be oxidized at the same level as that of the dense layer 6a, and the film quality of the porous layer 6b is not easily deteriorated. Consequently, the risk that the mechanical strength of the dense layer 6a and the adhesiveness of the interface between the dense layer 6a and the SiCN:H film 5 serving as the underlying film are lowered is very low.

The SiO₂ film 8 and the SiCN:H film 7 immediately below the SiO₂ film 8 are general insulating films each having a relative dielectric constant higher than that of the low-relative-dielectric-constant film unlike the SiCO:H film 6 which is the low-relative-dielectric-constant film (low-k film). Therefore, the SiO₂ film 8 and the SiCN:H film 7 have film densities and mechanical strengths higher than those of the SiCO:H film 6. Accordingly, the adhesiveness of the interface between the SiO₂ film 8 and the SiCN:H film 7 is higher than the adhesiveness of the interface between the SiO₂ film 107 and the SiCO:H film 106 according to the background art described above. For this reason, unlike in the semiconductor device 114 which is the comparative example in which peeling occurs on the interface between the SiO₂ film 107 and the SiCO:H film 106 in the CMP step, the risk that peeling occurs on the interface between the SiO₂ film 8 and the SiCN:H film 7 even in the CMP step is very low.

As described above, the SiCN:H film 7 serving as a sacrifice film is formed between the SiCO:H film 6 and the SiO₂ film 8. When the SiO₂ film 8 made of a material containing oxygen is formed above the SiCO:H film 6, the SiCN:H film 7 serves as a barrier film (layer) which blocks plasma oxygen ions generated from an N₂O gas which is one of the source gases of the SiO₂ film 8 from reaching the surface part 6a of the SiCO:H film 6. For this reason, even though plasma oxygen ions are generated from the N₂O gas in formation of the SiO₂ film 8, the risk that the oxygen ions reach the surface part 6a of the SiCO:H film 6 is very low. More specifically, in the formation of the SiO₂ film 8, the risk that the plasma oxygen ions react with the SiCO:H film 6 to cause the surface part 6a of the SiCO:H film 6 to adsorb moisture (H₂O) is very low.

Therefore, unlike in the semiconductor device 114 which is the comparative example, the risk is very low that, when the SiO₂ film 8 is formed above the SiCO:H film 6, the surface part 6a of the SiCO:H film 6 is oxidized by plasma oxygen ions to form a brittle layer (damage layer) on the surface part 6a of the SiCO:H film 6. As a result, even though the SiO₂ film 8 is formed above the SiCO:H film 6, the mechanical strength of the dense layer 6a formed on the surface part of the SiCO:H film 6 is kept increased enough to be resistant to stress applied in the CMP step, and the risk that the mechanical strength is lowered is very low. Similarly, the adhesiveness of the interface between the surface part (dense layer) 6a of the SiCO:H film 6 and the SiCN:H film 7 is also kept improved enough to be resistant to stress applied in the CMP, and the risk that the adhesiveness is lowered is very low.

In the embodiment, as the first insulating film arranged above the SiCO:H film 6, the SiO₂ film 8 made of a material containing oxygen is formed as described above. However, as in the embodiment, the first insulating film is not limited to the SiO₂ film according to the step of forming the SiCN:H film 7 between the SiCO:H film 6 and the first insulating film while performing a plasma processing to the SiCO:H film 6 under an oxygen-free atmosphere in which oxygen is substantially absent. For example, as the first insulating film, a film made of a material which does not contain oxygen atoms themselves and contains an element which reacts with oxygen like the SiCN:H film 7 is formed above the SiCO:H film 6, the same effect as that in the embodiment can be obtained. This will be briefly, concretely described below.

Although not shown, it is assumed that, for example, an SiC film, an SiN film, or the like is formed above the SiCO:H film 6 as the first insulating film made of a material containing an element reacting oxygen. At this time, as in the semiconductor device 114 which is the comparative example, it is assumed that a plasma processing is not performed to the SiCO:H film 6 under an atmosphere in which oxygen is substantially absent. Alternatively, it is assumed that the SiCN:H film 7 serving as a barrier film is formed between the SiCO:H film 6 and the SiC film or the SiN film. In this case, oxygen atoms (O) in the SiCO:H film 6 are coupled to carbon atoms (C) in the SiC film or nitrogen atoms (N) in the SiN film to form a film which easily adsorbs moisture (H₂O) of the SiO₂ film or the SiON film on the surface part of the SiCO:H film 6. As a result, as in the semiconductor device 114, a brittle layer is formed on the surface part of the SiCO:H film 6, and peeling or the like very easily occurs on the interface between the SiCO:H film 6 and the SiC film or the SiN film.

As described above, in the embodiment, a plasma processing is performed to the SiCO:H film 6 under the atmosphere in which oxygen is substantially absent to form the dense layer 6a on the surface part of the SiCO:H film 6. Accordingly, the SiCN:H film 7 serving as a barrier film is formed on the SiCO:H film 6 such that the SiCN:H film 7 is in direct contact with the SiCO:H film 6. In this manner, not only oxygen atoms in the surface part of the SiCO:H film 6 but also oxygen atoms in the porous layer 6b can be rarely coupled to carbon atoms in the SiC film on the SiCN:H film 7 or nitrogen atoms in the SiN film. Therefore, according to the embodiment, even though any one of the SiC film, the SiN film, and the like made of a material containing an element reacting with oxygen is employed as the first insulating film formed above the SiCO:H film 6, the risk that a brittle layer is formed on the surface part of the SiCO:H film 6 can be very low. Consequently, the risk that peeling occurs between the SiCO:H film 6 and another insulating film formed thereon can be very low.

In this manner, according to the embodiment, the adhesiveness and the mechanical strength near the interface between the SiCO:H film 6 which is a low-relative-dielectric-constant interlayer insulating film and the SiCN:H film 7 which is a general insulating film formed in direct contact with the SiCO:H film 6 are improved enough to be sufficiently resistant to stress generated in the CMP step. Accordingly, the adhesiveness between the SiCO:H film 6 and the SiO₂ film 8 which is another general insulating film indirectly stacked on the SiCO:H film 6 through the SiCN:H film 7 and the mechanical strength of the laminate film constituted by the three insulating film, i.e., the SiCO:H film 6, the SiCN:H film 7, and the SiO₂ film 8 are also improved enough to sufficiently resistant to stress generated in the CMP step. More specifically, the SiCO:H film 6, the SiCN:H film 7, and the SiO₂ film 8 are improved in resistance to stress (external force) applied by the CMP method or the like. For this reason, when the upper-layer interconnect 15 and the Cu via plug 16 are buried in the SiO₂ film 8, the SiCN:H film 7, the SiCO:H film 6, and the SiCN:H film 5, the risk that peeling occurs on interfaces among the films 6, 7, and 8, i.e., the SiCO:H film 6 to the SiO₂ film 8 is very low.

According to an experiment executed by the present inventors, unlike in the semiconductor device 114 which is the comparative example, peeling did not occur on the interfaces among the SiCO:H film 6, the SiCN:H film 7, and the SiO₂ film 8 according to the embodiment in the CMP step serving as a post-process of the film forming step. More specifically, according to the method of manufacturing a semiconductor device (film-forming method) of the embodiment, it has been found that defective peeling can be avoided which easily occurs near the interface between the SiCO:H film 6 and the SiCN:H film 7 when the conductor 14 is buried in the SiCO:H film 6 constituted by a low-relative-dielectric-constant insulating film and the SiCN:H film 7 formed in contact with the SiCO:H film 6. In the semiconductor device 17 according to the embodiment, peeling does not occur on the interface between the SiCO:H film 6 which is a low-relative-dielectric-constant interlayer insulating film and the SiCN:H film 5 which is a general insulating film serving as an underlying film of the SiCO:H film 6 in the CMP step as a matter of course. Also when the n-th interlayer insulating film 2 in which the Cu lower-layer interconnect 3 is buried is constituted by a low-relative-dielectric-constant film (SiCO:H film) like the (n+1)th interlayer insulating film 6, peeling does not occur on the interface between the SiCN:H film 5 and the n-th interlayer insulating film 2 in the CMP step as a matter of course.

According to an experiment executed by the present inventors, after the SiCO:H film 6 is deposited on the SiCN:H film 5, a plasma processing using an argon gas (argon ions) to the SiCO:H film 6 is continuously performed in the reaction vessel of the plasma CVD apparatus which forms the SiCO:H film 6. In this case, the same effect as that in the embodiment cannot be obtained. As a matter of fact, the defective peeling on the interfaces among the SiO₂ film 8, the SiCN:H film 7, and the SiCO:H film 6 is degraded, or the probability of occurrence of defective peeling increases. As a result of study committedly executed by the present inventors, it has been found that the cause is occurrence of the following phenomenon.

When the SiCO:H film 6 is formed by the plasma CVD method, the SiCO:H film 6 is deposited not only on the semiconductor substrate 1 but also in the reaction vessel. When a sputtering process is performed in the reaction vessel, SiCO:H molecules in the SiCO:H film 6 deposited in the reaction vessel, especially on a target electrode which is a counter electrode of a wafer electrode are sputtered by plasma ions. The sputtered SiCO:H molecules are excited in a plasma atmosphere to generate oxygen ions. In this case, it has been found that the generated oxygen ions react with the SiCO:H film 6 on the semiconductor substrate 1 to cause a chemical reaction expressed by the chemical equation (1) described in the comparative example. As a result obtained by the chemical reaction, it has been found that moisture (H₂O) is adsorbed on the surface part of the SiCO:H film 6 on the semiconductor substrate 1 to oxidize the surface part of the SiCO:H film 6.

Since the phenomenon occurs, the plasma processing is continuously performed to the SiCO:H film 6 in the reaction vessel in which the SiCO:H film 6 has been formed, in contrast, the defective peeling on the interfaces among the SiO₂ film 8, the SiCN:H film 7, and the SiCO:H film 6 may be degraded, or the probability that the defective peeling occurs may increase. Therefore, in order to obtain the effect of the embodiment, the plasma processing to the SiCO:H film 6 should not be continuously performed after the film-forming process of the SiCO:H film 6 in the reaction vessel in which the SiCO:H film 6 has been deposited.

Furthermore, according to an experiment executed by the present inventors, it has been found that, also when a precoat film made of a material free from oxygen is coated in the reaction vessel for depositing the SiO₂ film 8 as a pre-process of the step of forming the SiO₂ film 8 before the SiO₂ film 8 is formed by a plasma CVD method, the same effect as that in the embodiment can be obtained. For example, it has been found that, also when the SiO₂ film 8 is continuously formed by a plasma CVD method in the reaction vessel for depositing the SiO₂ film 8 after a precoat film except for an SiO₂ film is coated in the reaction vessel, the same effect as that in the embodiment can be obtained.

As described above, according to the first embodiment, as shown in FIG. 3D, the semiconductor device 17 can be easily obtained in which the Cu upper-layer interconnect 15 and the Cu via plug 16 having dual damascene structures are buried into the SiO₂ film 8, the SiCN:H film 7, the SiCO:H film 6, and the SiCN:H film 5, and peeling does not occur among at least the SiCO:H film 6, the SiCN:H film 7, and the SiO₂ film 8. More specifically, according to the first embodiment, the semiconductor device 17 can be easily manufactured in which the adhesiveness and the strength near the interface between the SiCO:H film 6 which is a low-relative-dielectric-constant interlayer insulating film and the SiCN:H film 7 or the SiO₂ film 8 which is another general insulating film directly or indirectly stacked on the SiCO:H film 6 are improved, and peeling is not caused by external force near the interfaces among the insulating films 6, 7, and 8.

Since peeling does not occur on the interfaces among the SiO₂ film 8, the SiCN:H film 7, the SiCO:H film 6, and the SiCN:H film 5 in the semiconductor device 17 according to the embodiment, the risk that the upper-layer interconnect 15 and the Cu via plug 16 buried in the films 5, 6, 7 and 8 are deteriorated is very low. More specifically, the risk that the buried interconnect (Cu upper-layer interconnect) 15 held by the semiconductor device 17 is deteriorated in quality, reliability, and the like is very low. Consequently, the risk that the semiconductor device 17 is deteriorated in quality, reliability, performance, and the like as a whole is very low. Therefore, the semiconductor device 17 can sufficiently and appropriately exert the desired functions for a long period of time. In other words, the semiconductor device 17 has a long life. Furthermore, as described above, a rate of occurrence of defective peeling is reduced in the semiconductor device 17, and thus, a production yield or productive efficiency is high.

### Second Embodiment

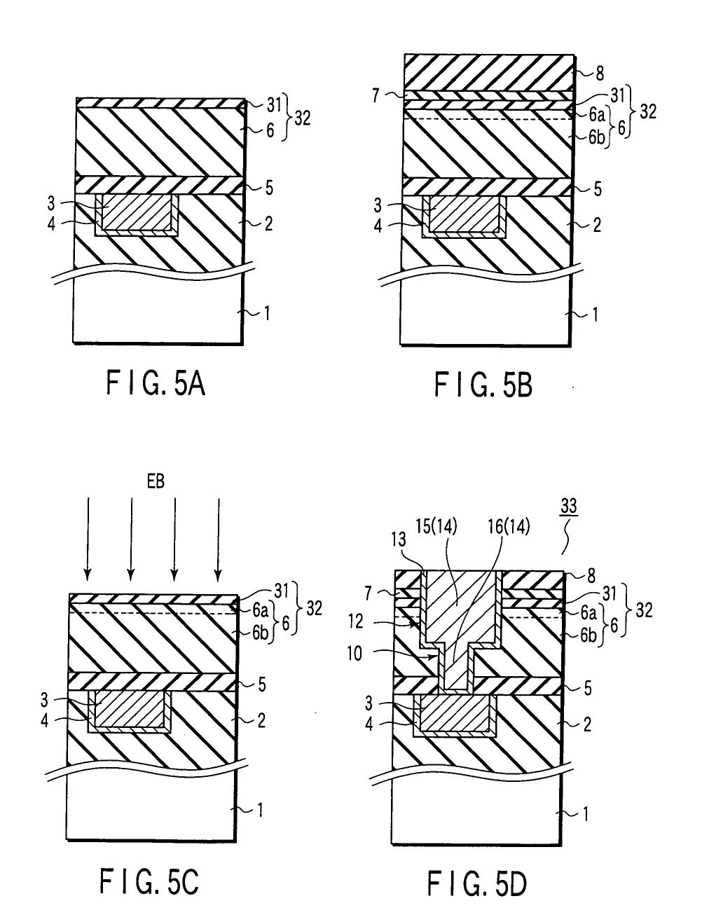

A second embodiment of the present invention will be described below with reference to FIGS. 5A to 5D. FIGS. 5A to 5D are process sectional views showing a method of manufacturing a semiconductor device according to the embodiment. The same reference numerals as in the first embodiment denote the same parts, and a description thereof will be omitted.

In the second embodiment, unlike in the first embodiment, there is not employed the step of, in order to prevent peeling on an interface (between films) between a low-relative-dielectric-constant interlayer insulating film and another general insulating film formed thereon, forming the another general insulating film on the low-relative-dielectric-constant interlayer insulating film while performing a plasma processing to a surface part of the low-relative-dielectric-constant interlayer insulating film. In the embodiment, before the another general insulating film is formed on the low-relative-dielectric-constant interlayer insulating film, the low-relative-dielectric-constant interlayer insulating film is formed to have a two-layer structure constituted by a first low-relative-dielectric-constant film and a second low-relative-dielectric-constant film. In this case, as the second low-relative-dielectric-constant film formed on the first low-relative-dielectric-constant film, a low-relative-dielectric-constant film which has a more dense film structure having a film density higher than that of the first low-relative-dielectric-constant film and which has a relative dielectric constant higher than that of the first low-relative-dielectric-constant film. After an electron beam is irradiated on the first and second low-relative-dielectric-constant films, the another general insulating film is formed on the second low-relative-dielectric-constant film. In this manner, peeling on the interface (between films) between the low-relative-dielectric-constant interlayer insulating film and the another general insulating film formed thereon is prevented. This will be described below in detail.

First, as shown in FIG. 5A, on a semiconductor substrate 1 on which a Cu lower-layer interconnect 3, an SiCN:H film 5 having a thickness of about 50 nm and serving as an etching stopper, and the like have been formed, an SiCO:H film 6 serving as a first low-relative-dielectric-constant film is formed by a plasma CVD method as in the first embodiment. Subsequently, another SiCO:H film 31 serving as a second low-relative-dielectric-constant film is formed on the surface of the SiCO:H film 6 by a plasma CVD method.

The relative dielectric constant of the SiCO:H film 31 is reduced to about 2.9, although the relative dielectric constant of a silicon dioxide (SiO₂) serving as a general interlayer insulating film is about 4.0. As described in the first embodiment, the SiCO:H film 6 has a relative dielectric constant of about 2.5. Therefore, the SiCO:H film 31 has a relative dielectric constant higher than that of the SiCO:H film 6. In relation to this, the film density of the SiCO:H film 31 is made higher than the film density of the SiCO:H film 6 and has a film structure denser than that of the SiCO:H film 6. More specifically, although the film density of the SiCO:H film 6 is about 1.1 g/cc, the film density of the SiCO:H film 31 is about 1.2 g/cc which is slightly higher than the film density of the SiCO:H film 6.

In formation of the SiCO:H film 31, a gas which is different from a source gas used in the formation of the SiCO:H film 6 and which contains organic silane having a cyclic structure is not used. More specifically, the SiCO:H film 31 is formed by using a gas containing an organic material such as trimethyl silane having a relatively low molecular weight. A film forming temperature (substrate temperature) at which the SiCO:H film 31 is formed is set at about 350° C. which is equal to the film forming temperature used when the SiCO:H film 6 is formed. The SiCO:H film 31 is deposited on the SiCO:H film 6 until the thickness of the SiCO:H film 31 is about 5 nm. In this manner, as shown in FIG. 5A, an (n+1)th low-relative-dielectric-constant interlayer insulating film 32 constituted by a laminate film having a two-layer structure constituted by the SiCO:H film 6 serving as a low-layer low-relative-dielectric-constant interlayer insulating film and the SiCO:H film 31 serving as an upper-layer low-relative-dielectric-constant interlayer insulating film is formed. In the following explanation, it is assumed that the SiCO:H film 6 and the SiCO:H film 31 are called a lower-layer SiCO:H film 6 and an upper-layer SiCO:H film 31, respectively in order to facilitate discrimination between the SiCO:H film 6 and the SiCO:H film 31.

The film-forming process of the upper-layer SiCO:H film 31 may be continuously performed in a reaction vessel 19 (film forming apparatus 18) used in formation of the lower-layer SiCO:H film 6 after the lower-layer SiCO:H film 6 is formed. Alternatively, the film-forming process of the upper-layer SiCO:H film 31 may be performed such that the semiconductor substrate 1 having the lower-layer SiCO:H film 6 formed thereon is moved from the reaction vessel 19 into another reaction vessel (film forming apparatus) (not shown) after the lower-layer SiCO:H film 6 is formed in the reaction vessel 19. In the formation of the upper-layer SiCO:H film 31, an atmosphere around the semiconductor substrate 1 may be set in a state in which a film-forming gas of the upper-layer SiCO:H film 31 and a film-forming gas of the lower-layer SiCO:H film 6 are not substantially mixed with each other. The semiconductor substrate 1 having the lower-layer SiCO:H film 6 formed thereon is preferably kept in a state in which the semiconductor substrate 1 is not exposed to the air or the like until the film-forming process of at least the upper-layer SiCO:H film 31 is finished. Furthermore, the semiconductor substrate 1 having the lower-layer SiCO:H film 6 and the upper-layer SiCO:H film 31 formed thereon is more preferably kept in a state in which the semiconductor substrate 1 is not exposed to the air or the like until at least electron beam irradiation (to be described later).

Next, as shown in FIG. 5B, an electron beam (EB) is irradiated on the upper-layer SiCO:H film 31, the lower-layer SiCO:H film 6, and the like. The electron beam irradiation is performed under the following settings. First, the semiconductor substrate 1 on which the upper-layer SiCO:H film 31 and the lower-layer SiCO:H film 6 have been formed is arranged under an atmosphere including an argon gas the pressure of which is reduced to about 5 Torr. Second, the temperature (substrate temperature) of the semiconductor substrate 1 on which the upper-layer SiCO:H film 31 and the lower-layer SiCO:H film 6 have been formed is set at about 350° C. Under the settings, an electron beam is irradiated on the upper-layer SiCO:H film 31 and the lower-layer SiCO:H film 6 such that a dose is set at about 130 μC/cm².

The electron beam irradiation densities (increases a density) the film structure of a brittle layer formed on the surface part 6a of the lower-layer SiCO:H film 6 to substantially eliminate the brittle layer. As a result, the surface part 6a of the lower-layer SiCO:H film 6 on which the upper-layer SiCO:H film 31 has been formed has a dense film structure the film density of which is equal to that of the upper-layer SiCO:H film 31. In other words, the surface part 6a of the lower-layer SiCO:H film 6 is deformed by irradiation of the electron beam into a dense layer having a film density of about 1.2 g/cc. Therefore, the electron-beam-irradiated lower-layer SiCO:H film 6 according to the embodiment, as shown in FIG. 5B, is formed as a low-relative-dielectric-constant interlayer insulating film substantially having a two-layer structure constituted by the dense layer 6a of the surface part and a porous layer 6b of a part except for the surface part, the dense layer 6a and the porous layer 6b having different film qualities in the same manner as in the SiCO:H film 6 of the first embodiment subjected to a plasma processing.

The surface part 6a of the lower-layer SiCO:H film 6 is substantially integrated with the upper-layer SiCO:H film 31 in the step (process) of increasing the film density of the surface part 6a to a film density almost equal to that of the upper-layer SiCO:H film 31. That is, the dense layer 6a is formed while being integrated with the upper-layer SiCO:H film 31. In this manner, upon completion of the step of forming the dense layer 6a, the dense layer 6a and the upper-layer SiCO:H film 31 substantially constitute a single-layer structure. As a result, the (n+1)th low-relative-dielectric-constant interlayer insulating film 32 on which the electron beam irradiation is finished is formed as a low-relative-dielectric-constant interlayer insulating film having a two-layer structure obtained by stacking two low-relative-dielectric-constant films of two types substantially having different film qualities. More specifically, the (n+1)th low-relative-dielectric-constant interlayer insulating film 32 on which the electron beam irradiation is finished, as shown in FIG. 5B, is formed as a low-relative-dielectric-constant laminate film constituted by the porous layer 6b serving as a lower-layer low-relative-dielectric-constant interlayer insulating film and a two-layer structure constituted by the dense layer 6a serving as an integrated upper-layer low-relative-dielectric-constant interlayer insulating film having a film density higher than that of the porous layer 6b and the upper-layer SiCO:H film 31. Upon completion of the electron beam irradiation on the upper-layer SiCO:H film 31 and the lower-layer SiCO:H film 6, the step of forming the (n+1)th low-relative-dielectric-constant interlayer insulating film 32 is ended.

Next, as shown in FIG. 5C, according to the same method as that in the first embodiment, an SiCN:H film 7 serving as a sacrifice film and an SiO₂ film 8 serving as a cap film are formed on the upper-layer SiCO:H film 31. The SiCN:H film 7 is deposited on the surface of the upper-layer SiCO:H film 31 until the thickness of the SiCN:H film 7 is about 2 nm. The SiO₂ film 8 is deposited on the surface of the SiCN:H film 7 until the thickness of the SiO₂ film 8 is about 100 nm. In formation of the SiCN:H film 7 serving as a sacrifice film, the upper-layer SiCO:H film 31 having a dense film structure is formed on the low-relative-dielectric-constant interlayer insulating film 32 serving as an underlying film in advance. For this reason, unlike in the first embodiment, the SiCN:H film 7 may be formed by a normal plasma CVD method using a gas containing organic silane and NH₃ as a source gas.

Next, as shown in FIG. 5D, according to the same method as that in the first embodiment, a via hole 10 and an upper-layer interconnect recessed part 12 are formed in the SiO₂ film 8, the SiCN:H film 7, the upper-layer SiCO:H film 31, the lower-layer SiCO:H film 6, and the SiCN:H film 5. Subsequently, a TaN film 13 and a Cu film 14 are formed in the via hole 10 and the upper-layer interconnect recessed part 12. Thereafter, the unnecessary TaN film 13 and the unnecessary Cu film 14 on the SiO₂ film 8 are polished and removed by a CMP method. In this manner, the TaN film 13 and the Cu film 14 are buried in the via hole 10 and the upper-layer interconnect recessed part 12 to form a Cu upper-layer interconnect 15 and a barrier metal film 13 which are formed integrally with the Cu via plug 16 and have damascene structures. By the steps up to now, as shown in FIG. 5D, a semiconductor device 33 having a desired buried interconnect structure is obtained. Also in the semiconductor device 33 of the second embodiment as in the semiconductor device 17 of the first embodiment, defective peeling does not occur on the interface between the SiCN:H film 5 and the n-th interlayer insulating film 2 serving as an underlying film of the SiCN:H film 5 and the interface between the SiCN:H film 7 and the SiO₂ film 8 serving as the upper-layer film of the SiCN:H film 7 in the CMP step as a matter of course.

As described above, in the second embodiment, the upper-layer SiCO:H film 31 which has a film structure denser than that of the lower-layer SiCO:H film 6 and a film density higher than that of the lower-layer SiCO:H film 6 is formed by using the low-film-density porous lower-layer SiCO:H film 6 as an underlying film. Both the upper and lower SiCO:H films 6 and 31 are formed by a plasma CVD method. After the upper-layer SiCO:H film 31 is formed on the lower-layer SiCO:H film 6, an electron beam is irradiated on the SiCO:H films 6 and 31. Thereafter, the SiO₂ film 8 is formed above the upper-layer SiCO:H film 31 by a plasma CVD method.

According to the film-forming method, when the SiO₂ film 8 serving as an upper-layer oxide film is formed by a plasma CVD method above the low-relative-dielectric-constant interlayer insulating film 32 (upper and lower SiCO:H films 6 and 31) serving as an underlying film, the surface part of the low-relative-dielectric-constant interlayer insulating film 32 can be easily suppressed from being oxidized by plasma oxygen ions and being made brittle, as in the first embodiment. Consequently, the mechanical strength of surface part of the low-relative-dielectric-constant interlayer insulating film 32 can be easily improved, and it is possible to easily secure the high adhesiveness of the interfaces among the low-relative-dielectric-constant interlayer insulating film 32, the SiCN:H film 7, and the SiO₂ film 8. Therefore, in the CMP step which is a post process of the step of forming the SiO₂ film 8, the risk that peeling occurs on the interfaces among the low-relative-dielectric-constant interlayer insulating film 32, the SiCN:H film 7, and the SiO₂ film 8 can be easily suppressed.

As a result, as shown in FIG. 5D, the semiconductor device 33 can be easily manufactured in which the Cu upper-layer interconnect 15 and the Cu via plug 16 having dual damascene structures are buried into the SiO₂ film 8, the SiCN:H film 7, the upper-layer SiCO:H film 31, the SiCO:H film 6, and the SiCN:H film 5, and peeling does not occur among at least the SiO₂ film 8, the SiCN:H film 7, the upper-layer SiCO:H film 31, and the lower-layer SiCO:H film 6. More specifically, according to the second embodiment, the semiconductor device 33 can be easily manufactured in which the adhesiveness and the strength near the interfaces among the SiCO:H films 6 and 31 which are the low-relative-dielectric-constant interlayer insulating film 32 and the SiCN:H film 7 and the SiO₂ film 8 which are other general insulating films directly or indirectly stacked on the upper and lower SiCO:H films 6 and 31 are improved, and peeling is not caused by external force near the interfaces among the insulating films 6, 31, 7, and 8. According to the second embodiment, the same effect as that in the first embodiment can be obtained.

As described above, in the embodiment, the upper-layer SiCO:H film 31 which has a film structure denser than that of the lower-layer SiCO:H film 6 and a film density higher than that of the lower-layer SiCO:H film 6 is formed on the lower-layer SiCO:H film 6 by a plasma CVD method. Therefore, in formation of the upper-layer SiCO:H film 31, plasma discharge of an oxygen gas is performed, and oxygen ions are generated as plasma-ionized oxygen. At this time, in general, as described in the first embodiment, the surface part 6a of the lower-layer SiCO:H film 6 serving as the underlying film of the upper-layer SiCO:H film 31 is oxidized by oxygen ions, and the risk that a brittle layer (not shown) is formed on the surface part 6a of the lower-layer SiCO:H film 6 is very high. Consequently, when an interconnect or the like is buried in the upper-layer SiCO:H film 31 and the lower-layer SiCO:H film 6 by a CMP method in the subsequent step, peeling very easily occurs on the interface between the upper-layer SiCO:H film 31 and the lower-layer SiCO:H film 6.

However, in the embodiment, as described above, an electron beam is irradiated on the upper-layer SiCO:H film 31 and the lower-layer SiCO:H film 6 after the upper-layer SiCO:H film 31 is formed on the lower-layer SiCO:H film 6. In this manner, the lower-layer SiCO:H film 6 becomes a low-relative-dielectric-constant interlayer insulating film substantially having a two-layer structure constituted by the dense layer 6a of the surface part and the porous layer 6b of a part except for the surface part, the dense layer 6a and the porous layer 6b having different film qualities. The lower-layer SiCO:H film 6 and the upper-layer SiCO:H film 31 integrated by the electron beam irradiation serve as a barrier layer (sacrifice film) which prevents oxygen ions or the like from reaching the porous layer 6b like the dense layer 6a formed on the surface part of the lower-layer SiCO:H film 6 by the plasma processing in the first embodiment. In this manner, the porous layer 6b can be suppressed from being oxidized by an oxygen plasma gas (oxygen ions) generated when the SiO₂ film 8 is deposited when the SiO₂ film 8 is deposited above the upper-layer SiCO:H film 31 by a plasma CVD method in a post-process. As described above, since the upper-layer SiCO:H film 31 has a film structure denser than that of the lower-layer SiCO:H film 6 and a film density higher than that of the lower-layer SiCO:H film 6, the upper-layer SiCO:H film 31 is not influenced by oxidization easily more than the lower-layer SiCO:H film 6. For this reason, the upper-layer SiCO:H film 31 is rarely deteriorated in film quality in the film-forming step. More specifically, the risk that the mechanical strength of the upper-layer SiCO:H film 31 and the adhesiveness between the upper-layer SiCO:H film 31 and the surface part 6a of the lower-layer SiCO:H film 6 are deteriorated is very low.

According to an experiment executed by the present inventors, it has been found that, when the low-relative-dielectric-constant interlayer insulating film 32 is formed by the film-forming method described above, defective peeling can be prevented from occurring on the interface between the upper-layer SiCO:H film 31 and the lower-layer SiCO:H film 6 in the CMP step which is a post-process, as in the first embodiment. Accordingly, it has been found that defective peeling can be prevented from occurring on the interface between the low-relative-dielectric-constant interlayer insulating film 32 and the SiCN:H film 5 serving as the underlying film of the low-relative-dielectric-constant interlayer insulating film 32 and the interface between the low-relative-dielectric-constant interlayer insulating film 32 and the SiCN:H film 7 serving as the upper-layer film of the low-relative-dielectric-constant interlayer insulating film 32 in the CMP step.

### Third Embodiment

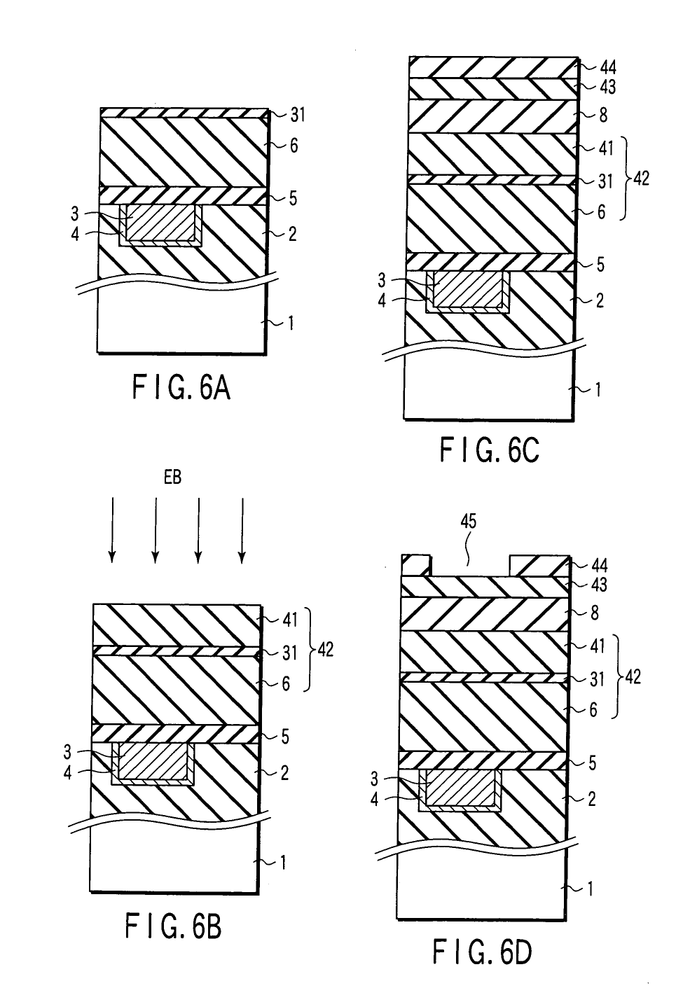

A third embodiment of the present invention will be described below with reference to FIGS. 6A to 6D, FIGS. 7A to 7D, and FIGS. 8A to 8D. FIGS. 6A to 8D are process sectional views showing a method of manufacturing a semiconductor device according to the third embodiment. The same reference numerals as in the first and second embodiments denote the same parts, and a description thereof will be omitted.

In the third embodiment, unlike in the first embodiment, there is not employed the step of, in order to prevent peeling on an interface (between films) between a low-relative-dielectric-constant interlayer insulating film and another general insulating film formed thereon, forming the another general insulating film on the low-relative-dielectric-constant interlayer insulating film while performing a plasma processing to a surface part of the low-relative-dielectric-constant interlayer insulating film. In the embodiment, as in the second embodiment, a two-layer structure constituted by a first low-relative-dielectric-constant film and a second low-relative-dielectric-constant film is formed. In addition, as the second low-relative-dielectric-constant film formed on the first low-relative-dielectric-constant film, a low-relative-dielectric-constant film is used which has a more dense film structure having a film density higher than that of the first low-relative-dielectric-constant film and which has a relative dielectric constant higher than that of the first low-relative-dielectric-constant film.

However, unlike in the second embodiment, a third low-relative-dielectric-constant film having a relative dielectric constant of 3.3 or less is formed on the second low-relative-dielectric-constant film before an electron beam is irradiated on the first and second low-relative-dielectric-constant films in the third embodiment. Thereafter, an electron beam is irradiated to the first, second, and third low-relative-dielectric-constant films. After the electron beam is irradiated on the first, second, and third low-relative-dielectric-constant films, another general insulating film is formed on the third low-relative-dielectric-constant film. In this manner, peeling on the interface (between films) between the low-relative-dielectric-constant interlayer insulating film and the other general insulating film formed thereon can be prevented. This will be described below.

First, as shown in FIG. 6A, on a semiconductor substrate 1 on which a Cu lower-layer interconnect 3, an SiCN:H film 5 having a thickness of about 50 nm and serving as an etching stopper, and the like have been formed, a lower-layer SiCO:H film 6 is formed by a plasma CVD method as in the first and second embodiments. The lower-layer SiCO:H film 6 is deposited on the SiCN:H film 5 until the thickness of the lower-layer SiCO:H film 6 is about 150 nm. Subsequently, an upper-layer SiCO:H film 31 is formed on the surface of the lower-layer SiCO:H film 6 by a plasma CVD method. The upper-layer SiCO:H film 31 is deposited on the lower-layer SiCO:H film 6 until the film thickness of the upper-layer SiCO:H film 31 is about 5 nm. A film forming temperature (substrate temperature) at which the upper and lower SiCO:H films 6 and 31 are formed is set at about 350° C. as in the first and second embodiment. However, in formation of the upper-layer SiCO:H film 31, a gas containing organic silane having a cyclic structure for use in formation of the lower-layer SiCO:H film 6 is not used. In the embodiment, in formation of the upper-layer SiCO:H film 31, a gas containing an organic material such as trimethyl silane having a relatively low molecular weight and O₂ is used as a source gas, as in the second embodiment.

Next, as shown in FIG. 6B, a third low-relative-dielectric-constant film 41 having a relative dielectric constant of 3.3 or less is formed on the surface of the upper-layer SiCO:H film 31 by a coating method. More specifically, a poly-arylene (PAr) film 41 is formed on the surface of the upper-layer SiCO:H film 31 by a spin coat method. The PAr film 41 is also a low-relative-dielectric-constant film like the upper and lower SiCO:H films 6 and 31. More specifically, the PAr film 41 is a low-relative-dielectric-constant film made of an organic resin having a relative dielectric constant of about 2.6. The PAr film 41 is coated on the surface of the upper-layer SiCO:H film 31 until the thickness of the PAr film 41 is about 150 nm.

In formation of the PAr film 41, as shown in FIG. 6B, an electron beam is irradiated on the PAr film 41 or the like on the semiconductor substrate 1 to perform heat treatment. The electron beam irradiation is performed under the same settings as those in the electron beam treatment in the second embodiment. More specifically, the semiconductor substrate 1 having the PAr film 41 coated thereon is arranged in an atmosphere including an argon gas the pressure of which is reduced to about 5 Torr. Accordingly, the temperature (substrate temperature) of the semiconductor substrate 1 is set at about 350° C. Under the settings, an electron beam is irradiated on the PAr film 41, the upper-layer SiCO:H film 31, the lower-layer SiCO:H film 6, and the like such that a dose is set at about 130 μC/cm². By the steps up to now, the PAr film 41 having a thickness of about 150 nm is formed on the surface of the upper-layer SiCO:H film 31. In this manner, as shown in FIG. 6B, an (n+1)th low-relative-dielectric-constant interlayer insulating film 42 is formed which is constituted by a low-relative-dielectric-constant laminate film having a three-layer structure constituted by the SiCO:H film 6 serving as a low-layer low-relative-dielectric-constant interlayer insulating film, the SiCO:H film 31 serving as an intermediate-layer low-relative-dielectric-constant interlayer insulating film, and the PAr film 41 serving as an upper layer low-relative-dielectric-constant interlayer insulating film.

Next, as shown in FIG. 6C, the SiO₂ film 8 is formed on the surface of the PAr film 41 by the same method as that in the first embodiment. That is, the SiO₂ film 8 is deposited on the surface of the PAr film 41 by a plasma CVD method using a gas mixture of gaseous SiH₄ and gaseous NH₃ as a source gas until the thickness of the SiO₂ film 8 is about 150 nm. Subsequently, an SiN film 43 is formed on the surface of the SiO₂ film 8. The SiN film 43 is deposited on the surface of the SiO₂ film 8 by the plasma CVD method using a gas mixture of gaseous SiH₄ and gaseous NH₃ as a source gas until the thickness of the SiN film 43 is about 100 nm. Subsequently, another SiO₂ film 44 is formed on the surface of the SiN film 43. The SiO₂ film 44 is deposited on the surface of the SiN film 43 by a plasma CVD method using a gas mixture of gaseous TEOS and gaseous O₂ as a source gas until the thickness of the SiO₂ film 44 is about 100 nm. Subsequently, although not shown, an upper-layer-interconnect-recessed-part-forming resist film to form an upper layer interconnect recessed part 45 is formed on the surface of the SiO₂ film 44.

Next, as shown in FIG. 6D, above the Cu lower-layer interconnect 3, the upper layer interconnect recessed part 45 is formed in the SiO₂ film 44. More specifically, as in the first embodiment, a pattern of the upper layer interconnect recessed part 45 is patterned in the upper-layer-interconnect-recessed-part-forming resist film by a photolithography method. Thereafter, the SiO₂ film 44 is etched by an RIE method using the patterned upper-layer-interconnect-recessed-part-forming resist film as a mask. In this manner, the upper layer interconnect recessed part 45 having a predetermined pattern which penetrates the SiO₂ film 44 is formed in the SiO₂ film 44 above the Cu lower-layer interconnect 3. Subsequently, the upper-layer-interconnect-recessed-part-forming resist film is peeled and removed from the surface of the SiO₂ film 44 by using an O₂ gas in a discharge state. Although not shown, a via-hole-forming resist film, made of an organic resin, for forming the via hole 46 is formed on the surface of the SiO₂ film 44 and the surface of the SiN film 43 the surface of which is partially exposed by the upper layer interconnect recessed part 45.

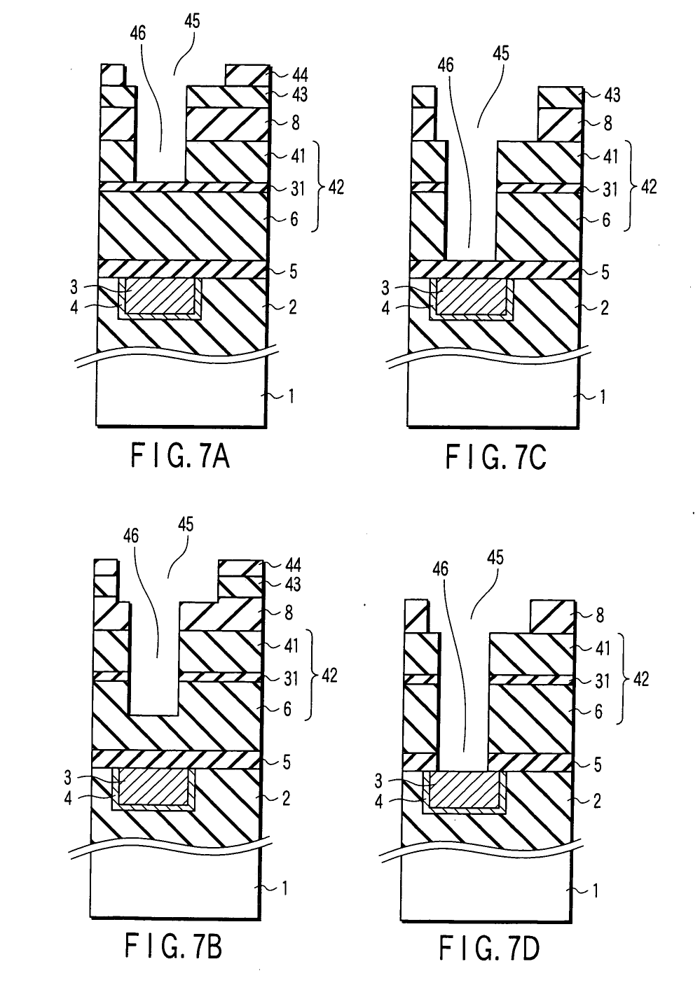

Next, as shown in FIG. 7A, the via hole 46 communicating with the upper layer interconnect recessed part 45 is formed in the SiN film 43, the SiO₂ film 8, and the PAr film 41, respectively. More specifically, as in the first embodiment, a pattern of the via hole 46 is patterned on a via-hole-forming resist film by a photolithography method. Thereafter, the SiN film 43, the SiO₂ film 8, and the PAr film 41 are etched by an RIE method using the patterned via-hole-forming resist film as a mask. In this manner, the via hole 46 having a predetermined pattern which penetrates the SiN film 43, the SiO₂ film 8, and the PAr film 41 to communicate with the upper layer interconnect recessed part 45 is formed in the films 43, 8, and 41. In this case, the via-hole-forming resist film is etched together with the PAr film 41 when the PAr film 41 which is an organic resin film like the via-hole-forming resist film is processed (etched). As a result, the via-hole-forming resist film is peeled and removed from the surface of the SiN film 43 in a self-aligning manner when the via hole 46 is formed.

Next, as shown in FIG. 7B, the SiN film 43 is etched by an RIE method using the SiO₂ film 44 patterned in the upper layer interconnect recessed part 45 as a mask, and the upper layer interconnect recessed part 45 is dug until the upper layer interconnect recessed part 45 penetrates the SiN film 43. In this manner, the upper layer interconnect recessed part 45 having the predetermined pattern is also formed in the SiN film 43. The upper-layer SiCO:H film 31 and the lower-layer SiCO:H film 6 are etched by the same method using the SiO₂ film 44 and the SiN film 43 as masks to dig the via hole 46. In this case, the via hole 46 is dug down until the via hole 46 penetrates the upper-layer SiCO:H film 31 to cause the lower end of the via hole 46 to reach an intermediate part of the lower-layer SiCO:H film 6.

Next, as shown in FIG. 7C, the lower-layer SiCO:H film 6 is etched by an RIE method to dig down the via hole 46 until the via hole 46 penetrates the lower-layer SiCO:H film 6 to partially expose the surface of the SiCN:H film 5. In this case, since the SiO₂ film 8 exposed under the SiN film 43 and the SiO₂ film 44 on the SiO₂ film 8 are films having Si—O bonds like the lower-layer SiCO:H film 6, the SiO₂ film 8 and the SiO₂ film 44 are etched when the lower-layer SiCO:H film 6 is etched. As a result, the SiO₂ film 44 is peeled and removed form the surface of the SiN film 43 in a self-aligning manner when the via hole 46 is formed.

Next, as shown in FIG. 7D, the SiCN:H film 5 is etched by an RIE method using the SiO₂ film 8 under the SiN film 43 as a mask to dig down the via hole 46 until the via hole 46 penetrates the SiCN:H film 5 to partially expose the surface of the Cu lower-layer interconnect 3. When the via hole 46 penetrates the SiCN:H film 5 to partially expose the surface of the Cu lower-layer interconnect 3, the step of forming the via hole 46 is ended. At this time, the SiN film 43 on the SiO₂ film 8 is etched together with the SiCN:H film 5. As a result, the SiN film 43 is peeled and removed from the surface of the SiO₂ film 8 in a self-aligning manner when the via hole 46 is formed.

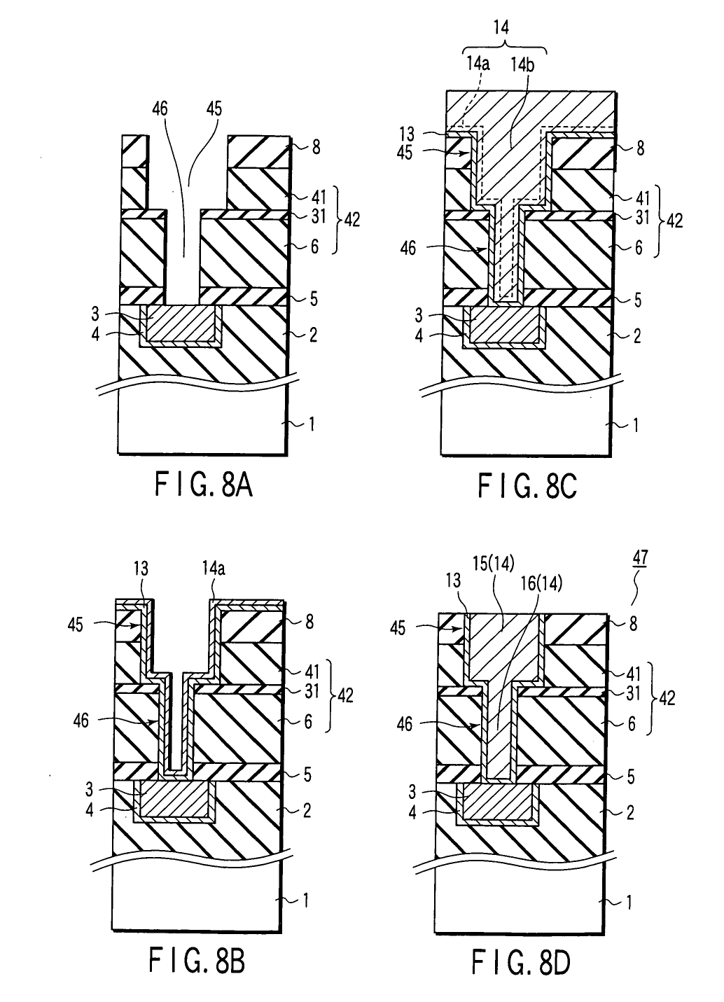

Next, as shown in FIG. 8A, the PAr film 41 is etched by an RIE method using the SiO₂ film 8 in which the upper layer interconnect recessed part 45 is patterned as a mask, and the upper layer interconnect recessed part 45 is dug down to penetrate the PAr film 41. In this manner, the upper layer interconnect recessed part 45 having the predetermined pattern is also formed in the PAr film 41. When the upper layer interconnect recessed part 45 is formed in the PAr film 41, the step of forming the upper layer interconnect recessed part 45 is ended. In the etching process of the PAr film 41, an NH₃ gas is used as an etching gas.

Next, as shown in FIG. 8B, a TaN film (barrier metal film) 13 is formed by a sputtering method in the via hole 46 and the upper layer interconnect recessed part 45 and on the SiO₂ film 8, as in the first embodiment. Subsequently, by the same sputtering method, a Cu underlying layer (Cu seed layer) 14a is formed on the TaN film 13.

Next, as shown in FIG. 8C, as in the first embodiment, the Cu plating film 14b is formed on the surface of the Cu seed layer 14a by an electrolytic plating method to bury the via hole 46 and the upper layer interconnect recessed part 45. At this time, the Cu seed layer 14a is integrated with the Cu plating film 14b to form a single Cu film 14.

Next, as shown in FIG. 8D, as in the first embodiment, the TaN film 13 and the Cu film 14 on the surface of the SiO₂ film 8 are polished and removed by a CMP method. In this manner, the TaN film 13 and the Cu film 14 are buried in the via hole 46 and the upper-layer interconnect recessed part 45. As a result, the Cu upper-layer interconnect 15 having a dual damascene structure integrated with the Cu via plug 16 is buried by the Cu film 14 in the SiO₂ film 8, the PAr film 41, the upper-layer SiCO:H film 31, the lower-layer SiCO:H film 6, and the SiCN:H film 5. The Cu upper-layer interconnect 15 serving as a buried interconnect is electrically connected to the lower-layer interconnect 3 through the Cu via plug 16 and the TaN film 13. By the steps up to now, as shown in FIG. 8D, a semiconductor device 47 having a desired buried interconnect structure is obtained.

As described above, the same effects as those in the first and second embodiments can be obtained according to the third embodiment. In the embodiment, the upper-layer SiCO:H film 31 serving as a dense layer is formed between the porous lower-layer SiCO:H film 6 and the PAr film 41 made of a polymer. In this manner, the upper-layer SiCO:H film 31 can function as a barrier film which suppresses the lower-layer SiCO:H film 6 from being deteriorated when the PAr film 41 is formed. The adhesiveness between the PAr film 41 and the lower-layer SiCO:H film 6 can be improved through the upper-layer SiCO:H film 31. Furthermore, since the PAr film 41 serving as a polymer coated film is formed on the surface of the upper-layer SiCO:H film 31 by using as an underlying film the upper-layer SiCO:H film 31 serving as a dense layer, the wettability of the PAr film 41 can be improved. Consequently, the mechanical strength of the (n+1)th low-relative-dielectric-constant interlayer insulating film 42 constituted by the PAr film 41, the upper-layer SiCO:H film 31, and the lower-layer SiCO:H film 6 can be easily improved. That is, the risk that peeling occurs in the low-relative-dielectric-constant interlayer insulating film 42 can be easily suppressed.

As a result, as shown in FIG. 8D, the semiconductor device 47 can be easily obtained in which the Cu upper-layer interconnect 15 and the Cu via plug 16 having dual damascene structures are buried into the SiO₂ film 8, the PAr film 41, the upper-layer SiCO:H film 31, the SiCO:H film 6, and the SiCN:H film 5, and peeling does not occur among at least the SiO₂ film 8, the PAr film 41, and the upper-layer SiCO:H film 31, and the lower-layer SiCO:H film 6. In other words, according to the third embodiment, the semiconductor device 47 can be easily manufactured in which the adhesiveness and the strength near the interfaces among the PAr film 41 and the upper and lower SiCO:H films 6 and 31 which are the (n+1)th low-relative-dielectric-constant interlayer insulating film 42 and the SiO₂ film 8 which is another general insulating film indirectly stacked on the upper and lower SiCO:H films 6 and 31 through the PAr film 41 are improved, and peeling is not caused by external force near the interfaces among the insulating films 6, 31, 41, and 8. The semiconductor device 47 according to the third embodiment has the same effects as those in the semiconductor device 17 of the first embodiment and the semiconductor device 33 of the second embodiment as a matter of course.

According to an experiment executed by the present inventors, peeling occurs on the interface between the PAr film 41 and the lower-layer SiCO:H film 6 in a CMP step when the upper-layer SiCO:H film 31 is not formed between the PAr film 41 and the lower-layer SiCO:H film 6. In contrast to this, according to the film-forming method of the embodiment, peeling does not occur on the interfaces among the PAr film 41, the upper-layer SiCO:H film 31, and the lower-layer SiCO:H film 6 which constitute the (n+1)th low-relative-dielectric-constant interlayer insulating film 42 in the CMP step. Consequently, peeling does not occur on the interface between the (n+1)th low-relative-dielectric-constant interlayer insulating film 42 and the SiO₂ film 8 serving as the upper-layer film of the (n+1)th low-relative-dielectric-constant interlayer insulating film 42 and the interface between the (n+1)th low-relative-dielectric-constant interlayer insulating film 42 and the SiCN:H film 5 serving as the underlying film of the (n+1)th low-relative-dielectric-constant interlayer insulating film 42 in the CMP step. In addition, peeling does not occurs on the interface between the SiCN:H film 5 and the n-th interlayer insulating film 2 serving as the underlying film of the SiCN:H film 5 as a matter of course.

According to another experiment executed by the present inventors, it has been found that, in formation of the PAr film 41, an electron beam is irradiated on the PAr film 41 or the like to make it possible to reduce heat load on the PAr film 41. It has been also found that the adhesivenesses of the interfaces between at least the PAr film 41 and the upper-layer SiCO:H film 31, between the upper-layer SiCO:H film 31 and the lower-layer SiCO:H film 6, and between the lower-layer SiCO:H film 6 and the SiCN:H film 5 can be improved. As in the first and second embodiments, it has been found that the mechanical strength of the lower-layer SiCO:H film 6 can be improved. Furthermore, it has been found that, due to the presence of the upper-layer SiCO:H film 31 serving as a dense layer immediately under the PAr film 41, the adhesive strength between the PAr film 41 and the upper-layer SiCO:H film 31 is increased from about 0.2 MPa·m^{1/2} to about 0.4 MPa·m^{1/2}, i.e., approximately doubled.

More specifically, it has been found that the mechanical strength and the adhesiveness of the (n+1)th low-relative-dielectric-constant interlayer insulating film 42 having the three-layer structure can be resistant to stress generated in the CMP step and are improved enough to prevent peeling from occurring on the interfaces among the low-relative-dielectric-constant films 6, 31, and 41. Consequently, it has been found that the adhesiveness between the low-relative-dielectric-constant interlayer insulating film 42 and the SiCN:H film 5 serving as the underlying film of the low-relative-dielectric-constant interlayer insulating film 42 and the adhesiveness between the low-relative-dielectric-constant interlayer insulating film 42 and the SiO₂ film 8 serving as the upper-layer film of the low-relative-dielectric-constant interlayer insulating film 42 are improved enough to be resistant to stress generated in the CMP step and to prevent peeling from occurring on the interfaces among the insulating films 5, 42, and 8.

As described above, in the embodiment, an NH₃ gas is used as an etching gas when the PAr film 41 is etched by an RIE method to dig down the upper layer interconnect recessed part 45. In this case, the film quality of the lower-layer SiCO:H film 6 serving as the underlying film of the PAr film 41 may be deteriorated by the NH₃ gas. This phenomenon may be caused by occurrence of the following chemical reaction between the lower-layer SiCO:H film 6 and the NH₃ gas. The deterioration phenomenon of the film quality of the lower-layer SiCO:H film 6 caused by the NH₃ gas will be described below with reference to typical chemical reactions.

Since the lower-layer SiCO:H film 6 is an almost porous film having weak bonding force, the lower-layer SiCO:H film 6 easily reacts with the NH₃ gas. More specifically, when the NH₃ gas adheres to the surface of the lower-layer SiCO:H film 6, methyl radicals of the surface part of the lower-layer SiCO:H film 6 react with hydrogen (H) in the NH₃ gas to cause a chemical reaction expressed by the following chemical equation (2).
≡Si—CH₃+H→≡Si—+CH₄ (2)

Subsequently, the surface part of the lower-layer SiCO:H film 6 further reacts moisture (H₂O) in the atmosphere to cause a chemical reaction expressed by the following chemical equation (3).
2≡Si—+H₂O→≡Si—OH+≡Si—H (3)

In the chemical equation (2), ≡Si—CH₃ denotes a methyl radical contained in the lower-layer SiCO:H film 6. A hydroxyl function (≡Si—OH) generated by the chemical reaction expressed by the chemical equation (3) functions as a so-called moisture-absorption site which adsorbs moisture (H₂O). For this reason, when the NH₃ gas is used as an etching gas in formation of the upper layer interconnect recessed part 45, moisture easily adheres to the surface of the lower-layer SiCO:H film 6. When the Cu upper-layer interconnect 15 is formed in the upper layer interconnect recessed part 45, the Cu upper-layer interconnect 15 is easily oxidized (corroded) and deteriorated. As a result, the interconnect easily decreases in reliability and performance.

However, in the third embodiment, the upper-layer SiCO:H film 31 having a film structure which is denser than that of the lower-layer SiCO:H film 6 is formed on the lower-layer SiCO:H film 6 as in the second embodiment. As described in the first and second embodiments, the upper-layer SiCO:H film 31 which is a dense layer is not easily oxidized. For this reason, an influence (oxidization) of the NH₃ gas to the lower-layer SiCO:H film 6 is reduced by the presence of the upper-layer SiCO:H film 31 which is a dense layer. In other words, when the PAr film 41 is etched to dig down the upper layer interconnect recessed part 45, damage of the NH₃ gas to the lower-layer SiCO:H film 6 is reduced by the upper-layer SiCO:H film 31. As a result, in the semiconductor device 47 according to the embodiment and the method of manufacturing the same, the risk that the Cu upper-layer interconnect 15 is considerably deteriorated in reliability and performance is very low. This is true in the TaN film (barrier metal film) 13 formed to cover the Cu upper-layer interconnect 15. As a result, the interconnect structure of the embodiment is improved in reliability and performance.

The chemical reactions expressed by the chemical equations (2) and (3) are only several typical chemical reactions of various chemical reactions caused between the lower-layer SiCO:H film 6 and the NH₃ gas. Actually, various chemical reactions except for the chemical reactions expressed by the chemical equations (2) and (3) occur between the lower-layer SiCO:H film 6 and the NH₃ gas.

The method of manufacturing a semiconductor device according to the present invention is not limited to the first to third embodiments. The method can be executed by changing some configurations, some manufacturing steps, or the like of the first to third embodiments into various settings or using appropriate combinations of the various settings without departing from the spirit and scope of the invention.

For example, although the plasma processing to the lower-layer SiCO:H film 6 and the film-forming process of the SiCN:H film 7 are performed in the same step in the first embodiment, this configuration does not limit the invention. The plasma processing to the lower-layer SiCO:H film 6 and the film-forming process of the SiCN:H film 7 may be performed in different steps, respectively.

Although the SiCN:H film 27 is employed as a precoat film formed in the reaction vessel 19 in the first and second embodiments, the SiCN:H film 27 does not limit the invention. The precoat film 27 may be formed by a material including at least an element except for oxygen (O). More preferably, the precoat film 27 may be formed by a material which is free from oxygen and contains at least one element of silicon (Si), carbon (C), and nitrogen (N). For example, an SiCN:H film may be formed as the precoat film 27 by using a gas mixture of monosilane (SiH₄) and ammonia (NH₃). Alternatively, an SiC:H film is employed in place of the SiCN:H film 27, the same antioxidant effect as that of the SiCN:H film 27 can be obtained when a film-forming process is performed in the reaction vessel 19.

Similarly, although an argon gas is used as a gas for plasma processing to the lower-layer SiCO:H film 6 or the upper-layer SiCO:H film 31 in the first and second embodiments, the gas for plasma processing is not limited to the argon gas. A gas containing a noble gas as a main component may be used as the gas for plasma processing. For example, also when a gas containing at least one element of helium (He), neon (Ne), krypton (Kr), xenon (Xe), and radon (Rn) as a main component in place of argon (Ar), the same effects as those in the first and second embodiments can be obtained. Alternatively, a plasma processing to the lower-layer SiCO:H film 6 or the upper-layer SiCO:H film 31 may be performed more than once by using noble gases of different types. For example, after a plasma processing is performed to the lower-layer SiCO:H film 6 or the upper-layer SiCO:H film 31 by using a plasma argon gas, a plasma processing may be continuously performed by using a plasma helium gas. According to an experiment executed by the present inventors, it has been confirmed that the same effects as those in the first and second embodiments can be obtained by using the plasma processing described above.

The plasma process to the SiCO:H film or the like in the first embodiment and the electron beam irradiation in the second and third embodiments are performed at about 350° C. which is equal to the film-forming temperatures of the SiCO:H films in the first to the third embodiments. However, the set temperatures are not limited to 350° C. According to an experiment executed by the present inventors, it has been confirmed that, when a temperature at which a plasma processing or electron beam irradiation is performed to the SiCO:H film or the like is about 450° C. or less, the same effects as those in the first to third embodiments can be obtained.

In the second and third embodiments, organic silane which is not contained in the film-forming material of the porous lower-layer SiCO:H film 6 is used as one of film-forming materials of the upper-layer SiCO:H film 31 serving as a dense layer, but different materials are not always used. According to an experiment executed by the present inventors, it has been confirmed that, even though the same source gas as the film-forming material of the lower-layer SiCO:H film 6 is used as the film-forming material of the upper-layer SiCO:H film 31, the same effect as described above can be obtained by optimizing discharging conditions.

The effects obtained by the first to third embodiments are not limited to the same interconnect structures as those in the semiconductor devices 17, 33, and 47 in the first to third embodiments. According to an experiment executed by the present inventors, it has been confirmed that, when an interconnect structure of at least one type of the interconnect structures shown in FIGS. 3D, 5D, and 8D is applied as a part of the internal interconnect structure of the semiconductor device, the same effects as those in the first to third embodiments can be obtained. The effects obtained by the first to third embodiments are not limited to the dual damascene structures described in the first to third embodiments. According to an experiment executed by the present inventors, it has been confirmed that the same effects as those in the first to third embodiments can be obtained even in a so-called single damascene structure in which the upper-layer interconnect 15 and the via plug 16 are independently formed. Furthermore, the materials of the upper-layer interconnect 15, the via plug 16, and the lower-layer interconnect 3 are not limited to Cu. According to an experiment executed by the present inventors, it has been confirmed that, even though the upper-layer interconnect 15, the via plug 16, and the lower-layer interconnect 3 are made of aluminum (Al), the same effects as those in the first to third embodiments can be obtained. Moreover, the material of the barrier metal film 13 is not limited to TaN. According to an experiment executed by the present inventors, it has been confirmed that the same effects as those in the first to third embodiments can be obtained even though the barrier metal film 13 is formed by a material containing not only Ta but also, for example, Nb, W or Ti.

Although the SiCO:H films 6 and 31 are used as main low-relative-dielectric-constant interlayer insulating films in the first to third embodiments, the low-relative-dielectric-constant interlayer insulating films are not limited to the SiCO:H films. As the low-relative-dielectric-constant interlayer insulating film, a low-relative-dielectric-constant film containing at least oxygen and having a relative dielectric constant of 3.3 or less may be used. Preferably, a low-relative-dielectric-constant interlayer insulating film made of a material containing oxygen and at least one element of silicon (Si), carbon (C), and hydrogen (H) is used, the same effects as those in the first to third embodiments can be obtained. Similarly, although the SiO₂ films 8 and 44 are used as the upper-layer oxide films of the low-relative-dielectric-constant interlayer insulating films in the first to third embodiments, the upper-layer oxide film is not limited to the SiO₂ film. The upper-layer oxide film may be formed by a material containing oxygen. Preferably, when an upper-layer oxide film made of a material containing oxygen and at least silicon (Si) is used, the same effects as those in the first to third embodiments can be obtained.

In the first embodiment, a high-frequency voltage of about 13.56 MHz is applied to the upper electrode 21 when the SiCN:H film 27 is precoated on the inside (processing chamber 20) of the reaction vessel 19. However, the high-frequency voltage is not limited to about 13.56 MHz. The value of the high-frequency voltage applied to the upper electrode 21 may be appropriately set depending on the film quality, the film thickness, and the like of the precoat film 27 such that the precoat film 27 is appropriately formed.

Furthermore, the plasma CVD apparatus 18 used in the first and second embodiments is not used to form only the SiCN:H film 27. By using the plasma CVD apparatus 18, films of different types may be formed on the semiconductor substrate 1 in the reaction vessel 19. In this case, for example, after a film of one type is formed in the reaction vessel 19, an etching gas (cleaning gas) which etches and decomposes the film adhering to the inside of the reaction vessel 19 into a gas is supplied into the reaction vessel 19 through the air-supply holes 21a of the air-supply nozzle (upper electrode) 21. After the film adhering to the inside of the reaction vessel 19 is decomposed into a gas not to influence the next film-forming process, the gas and the gas in the reaction vessel 19 may be exhausted out of the reaction vessel 19 through the exhaust pipe 25 and the vacuum pump 26. Thereafter, a gas serving as a material of a precoat film suitable for the next film-forming process is supplied into the reaction vessel 19 through the air-supply holes 21a of the air-supply nozzle (upper electrode) 21, and a new precoat film may be coated on the inside of the reaction vessel 19. When these steps are repeated to make it possible to form high-quality insulating films of different types such that the insulating films are rarely deteriorated in film quality by oxidization to the low-relative-dielectric-constant films by using one plasma CVD apparatus 18.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device, comprising:
providing a low-relative-dielectric-constant film above a substrate, the low-relative-dielectric-constant film containing at least oxygen (O) and having a relative dielectric constant of 3.3 or more, a conductor being to be buried in the low-relative-dielectric-constant film;
performing a plasma processing by discharging a gas containing a noble gas as a main component to the low-relative-dielectric-constant film, the plasma processing being executed while the substrate above which the low-relative-dielectric-constant film is provided is storing in a processing chamber having an inside covered with a material composed of an element except for oxygen and substantially set under an oxygen-free atmosphere; and
providing a first insulating film above the low-relative-dielectric-constant film by a plasma CVD method, the first insulating film being made of a material containing at least one of a material containing oxygen and a material containing an element reacting with oxygen, a conductor being to be buried in the first insulating film.

2. The method according to claim 1, further comprising:
providing a second insulating film on the low-relative-dielectric-constant film before the first insulating film is provided, the second insulating film being made of an element except for oxygen, a conductor being to be buried in the second insulating film, and the second insulating film being provided in the processing chamber while performing the plasma processing to the low-relative-dielectric-constant film, keeping the substrate above which the low-relative-dielectric-constant film is provided is under an oxygen-free atmosphere until formation of the second insulating film is finished.

3. The method according to claim 1, wherein
the low-relative-dielectric-constant film is formed by using a material containing oxygen (O) and at least one element of silicon (Si), carbon (C), and hydrogen (H).

4. The method according to claim 1, wherein
the first insulating film is formed by using a material at least containing at least one of oxygen and an element reacting with oxygen, and silicon (Si).

5. The method according to claim 1, wherein
the plasma processing is performed in another processing chamber different from a processing chamber using to provide the low-relative-dielectric-constant film.

6. The method according to claim 1, wherein
the plasma processing is performed by using a gas containing at least one element of argon (Ar), helium (He), neon (Ne), krypton (Kr), xenon (Xe), and radon (Rn) as a main component.

7. The method according to claim 1, wherein
the plasma processing is performed more than once by using gases of different types containing different noble gas elements as main components.

8. The method according to claim 1, wherein
the plasma processing is performed at about 450° C. or less.

9. The method according to claim 2, wherein
the inside of the processing chamber is covered with the same material as that of the second insulating film before the second insulating film is provided.

10. The method according to claim 2, wherein
the inside of the processing chamber is covered with a material containing silicon (Si) and at least one of carbon (C) and nitrogen (N) before the second insulating film is provided.

11. A manufacturing method of a semiconductor device, comprising:
providing a first low-relative-dielectric-constant film above a substrate, the first low-relative-dielectric-constant film containing at least oxygen (O), and having a relative dielectric constant of 3.3 or less, a conductor being to be buried in the first low-relative-dielectric-constant film;
providing a second low-relative-dielectric-constant film on the first low-relative-dielectric-constant film, the second low-relative-dielectric-constant film containing at least oxygen (O), having a relative dielectric constant of 3.3 or less and having a film density higher than that of the first low-relative-dielectric-constant film, a conductor being to be buried in the second low-relative-dielectric-constant film; and
irradiating an electron beam on at least the first and second low-relative-dielectric-constant films.

12. The method according to claim 11, further comprising:
providing a first insulating film above the second low-relative-dielectric-constant film by a plasma CVD method after the electron beam is irradiated on the first and second low-relative-dielectric-constant films, the first insulating film being made of a material containing at least one of oxygen and an element reacting with oxygen, a conductor being to be buried in the first insulating film.

13. The method according to claim 11, further comprising:
providing a third low-relative-dielectric-constant film on the second low-relative-dielectric-constant film by a coating method before the electron beam is irradiated on the first and second low-relative-dielectric-constant films, the third low-relative-dielectric-constant film having a relative dielectric constant of 3.3 or less, and the electron beam being irradiating on the first, second, and third low-relative-dielectric-constant films after the third low-relative-dielectric-constant film is provided on the second low-relative-dielectric-constant film.

14. The method according to claim 11, wherein
the first and second low-relative-dielectric-constant films are formed by using a material containing oxygen (O) and at least one element of silicon (Si), carbon (C), and hydrogen (H).

15. The method according to claim 11, wherein
the substrate provided the first low-relative-dielectric-constant film there above is kept under an oxygen-free atmosphere at least until completing the formation of the second low-relative-dielectric-constant film.

16. The method according to claim 11, wherein
the electron beam irradiation is performed at about 450° C. or less.

17. The method according to claim 12, wherein
the first insulating film is formed by using a material at least containing at least one of oxygen and an element reacting with oxygen, and silicon (Si).

18. The method according to claim 12, further comprising:
providing a second insulating film on the second low-relative-dielectric-constant film before the first insulating film is provided, the second insulating film being made of an element except for oxygen, a conductor being to be buried in the second insulating film.

19. The method according to claim 18, wherein
the second insulating film is provided while performing a plasma processing to the second low-relative-dielectric-constant film in a processing chamber having an inside covered with a material containing silicon (Si) and at least one of carbon (C) and nitrogen (N) and substantially set under an oxygen-free atmosphere.

20. The method according to claim 13, wherein
the third low-relative-dielectric-constant film is formed by an organic resin.
